(19) United States
(12) Patent Application Publication
(10) Pub. No.: US 2025/0324843 A1
(43) Pub. Date: Oct. 16, 2025

(54) PHOTOELECTRIC DEVICE MODULE AND OPERATION METHOD THEREOF

(71) Applicant: Raynergy Tek Incorporation, HSINCHU (TW)

(72) Inventors: Yi-Ming CHANG, HSINCHU (TW); Ping-Yen CHEN, HSINCHU (TW)

(21) Appl. No.: 19/026,433

(22) Filed: Jan. 17, 2025

Related U.S. Application Data
(60) Provisional application No. 63/633,044, filed on Apr. 11, 2024.

(30) Foreign Application Priority Data
Oct. 23, 2024 (TW) 113140420

(51) Int. Cl. H10K 30/87

(52) U.S. Cl. CPC H10K 30/87

(57) ABSTRACT

The present disclosure provides a photoelectric device module including a substrate, a first reflective layer, a photoelectric conversion layer, and a second reflective layer. The first reflective layer is disposed on the substrate, in which the first reflective layer has a first reflectivity. The photoelectric conversion layer is disposed on the first reflective layer and has a thickness of greater than or equal to 135 nm. The second reflective layer is disposed on the photoelectric conversion layer, in which the second reflective layer has a second reflectivity, and the first reflectivity is greater than the second reflectivity.

### CROSS-REFERENCE TO RELATED APPLICATION

This application claims priority to U.S. Provisional Application Ser. No. 63/633,044, filed Apr. 11, 2024, and Taiwan Application Serial Number 113140420, filed Oct. 23, 2024, the disclosures of which are incorporated herein by reference in their entireties.

### BACKGROUND

### Field of Invention

The present disclosure relates to a photoelectric device module and an operation method thereof.

### Description of Related Art

To improve the performance of photosensors or image sensors (e.g., high photoelectric conversion efficiency, high brightness, high sensitivity, wide emission wavelength range, and/or wide photosensitive wavelength range) and reduce their cost, many new materials, such as organic semiconductors, have been developed for application.

The advantage of using organic semiconductors as photoelectric conversion materials is that their spectral response range is wider than that of the traditional material silicon. In addition, some organic semiconductors have a small optical energy gap and can respond to short-wave infrared (SWIR) light with a wavelength greater than or equal to 1000 nm. However, the organic semiconductors have a lower absorption coefficient. Therefore, the external quantum efficiency (EQE) of photosensors or image sensors using the organic semiconductors as the photoelectric conversion layer is usually low.

### SUMMARY

The present disclosure provides a photoelectric device module including a substrate, a first reflective layer, a photoelectric conversion layer, and a second reflective layer. The first reflective layer is disposed on the substrate, in which the first reflective layer has a first reflectivity. The photoelectric conversion layer is disposed on the first reflective layer and has a thickness of greater than or equal to 135 nm. The second reflective layer is disposed on the photoelectric conversion layer, in which the second reflective layer has a second reflectivity, and the first reflectivity is greater than the second reflectivity.

In some embodiments, the thickness of the photoelectric conversion layer is 135 nm to 500 nm.

In some embodiments, the first reflective layer has the first reflectivity of greater than or equal to 50%, and the second reflective layer has the second reflectivity of greater than or equal to 5%.

In some embodiments, the second reflectivity is less than or equal to 50%.

In some embodiments, the photoelectric device module further includes a carrier transport layer disposed between the first reflective layer and the photoelectric conversion layer or between the photoelectric conversion layer and the second reflective layer.

In some embodiments, the carrier transport layer has a thickness of 10 nm to 100 nm.

In some embodiments, the first reflective layer has a thickness of greater than or equal to 50 nm.

In some embodiments, the first reflective layer includes silver (Ag), aluminum (Al), copper (Cu), gold (Au), titanium (Ti), tungsten (W), molybdenum (Mo), titanium nitride (TiN), or combinations thereof.

In some embodiments, the second reflective layer has a thickness of 50 nm to 300 nm.

In some embodiments, the second reflective layer includes a transparent conductive oxide (TCO), a transparent conductive polymer, silver nanowires, a metal-containing layer with a thickness of less than or equal to 15 nm, or combinations thereof.

In some embodiments, the photoelectric conversion layer has an optical energy gap of less than or equal to 1.24 eV.

In some embodiments, the thickness of the photoelectric conversion layer is 135 nm to 500 nm.

In some embodiments, the photoelectric device module further includes a carrier transport layer disposed between the first reflective layer and the photoelectric conversion layer, in which the carrier transport layer is a hole transport layer or an electron transport layer.

In some embodiments, the carrier transport layer has a thickness of 10 nm to 100 nm.

In some embodiments, the first reflective layer has the first reflectivity of greater than or equal to 50% for light with a wavelength of 600 nm to 2600 nm.

The present disclosure provides a method of operating a photoelectric device module, and the method includes receiving light by the photoelectric device module of any one of the foregoing embodiments, in which an upper surface of the second reflective layer is a light-receiving surface.

### BRIEF DESCRIPTION OF THE DRAWINGS

The present disclosure can be more fully understood by reading the following detailed description of the embodiments, with reference made to the accompanying drawings.

FIG. 1 is a schematic cross-sectional view of a photoelectric device module according to various embodiments of the present disclosure.

FIG. 2 is a schematic cross-sectional view of the photoelectric device modules of Examples 1-23.

FIG. 3 shows an absorption spectrum of the P-type organic semiconductor and the N-type organic semiconductor of the photoelectric conversion layers of Examples 1-19 and Comparative Examples 1-4.

FIG. 4, FIG. 5, FIG. 6, FIG. 7, and FIG. 8 are external quantum efficiency-wavelength diagrams of the photoelectric device modules of Examples 1-7, 8-10, 11-16, 17-19, and 20-23, respectively.

FIG. 9 is a schematic cross-sectional view of the photoelectric device modules of Comparative Examples 1-8.

FIG. 10 and FIG. 11 are external quantum efficiency-wavelength diagrams of the photoelectric device modules of Comparative Examples 1-4 and Comparative Examples 5-8, respectively.

### DETAILED DESCRIPTION

The following embodiments are disclosed with accompanying diagrams for detailed description. For illustration clarity, many details of practice are explained in the following descriptions. However, it should be understood that these details of practice do not intend to limit the present disclosure. That is, these details of practice are not necessary in parts of embodiments of the present disclosure. Furthermore, for simplifying the drawings, some of the conventional structures and elements are shown with schematic illustrations.

It should be understood that although terms “first,” “second,” “third,” etc. may be used herein to describe various elements, components, regions, layers, and/or blocks, these elements, components, regions, layers, and/or sections should not be limited by these terms. These terms are only used to distinguish a single element, component, region, layer, or section from another element, component, region, layer, or section. Thus, a first element, component, region, layer, or section hereinafter could be termed as a second element, component, region, layer, or section without departing from the teachings of the present disclosure.

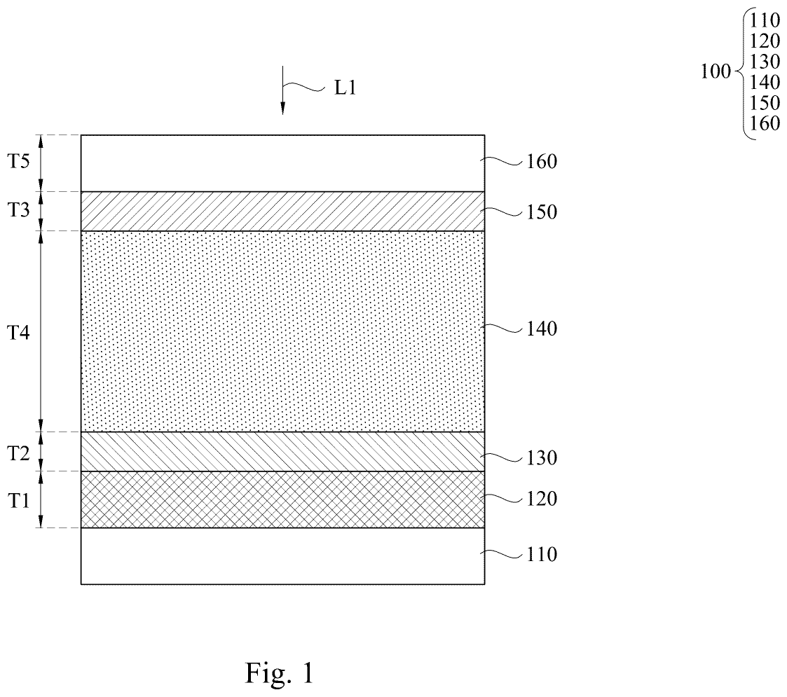

The present disclosure provides a photoelectric device module. FIG. 1 is a schematic cross-sectional view of a photoelectric device module 100 according to various embodiments of the present disclosure. As shown in FIG. 1, the photoelectric device module 100 includes a substrate 110, a first reflective layer 120, a first carrier transport layer 130, a photoelectric conversion layer 140, a second carrier transport layer 150, and a second reflective layer 160. The first reflective layer 120 is disposed on the substrate 110, in which the first reflective layer 120 has a first reflectivity. The first carrier transport layer 130 is disposed on the first reflective layer 120. The photoelectric conversion layer 140 is disposed on the first carrier transport layer 130 and has a thickness T4 greater than or equal to 135 nm. The second carrier transport layer 150 is disposed on the photoelectric conversion layer 140. The second reflective layer 160 is disposed on the second carrier transport layer 150, in which the second reflective layer 160 has a second reflectivity, and the first reflectivity is greater than the second reflectivity. In some embodiments, the first reflective layer 120 has the first reflectivity of greater than or equal to 50%, such as 50, 55, 60, 65, 70, 75, 80, 85, 90, or 95%. In some embodiments, the first reflective layer 120 has the first reflectivity of greater than or equal to 50% for light with a wavelength of 600 nm to 2600 nm. When the first reflectivity is higher, more light can be reflected by the first reflective layer 120 and enter the photoelectric conversion layer 140. In some embodiments, the second reflective layer 160 has the second reflectivity greater than or equal to 5%. For example, the second reflectivity may be greater than or equal to 5, 10, 15, 20, 25, or 30%. In addition, the second reflectivity can be less than or equal to 50%, so that the photoelectric device module 100 can still receive enough light for photoelectric conversion. In some embodiments, the photoelectric device module 100 further includes external wires or circuit structures (not shown) that read or collect signals and currents generated by the photoelectric conversion layer 140. For example, the external wires and/or circuit structures are provided in the substrate 110. The photoelectric device module 100 can be used as a photosensitive element or an image sensing element.

The present disclosure provides a method of operating the photoelectric device module 100, and the method includes receiving light L1 by the photoelectric device module 100, in which the upper surface of the second reflective layer 160 is a light-receiving surface. Since the photoelectric device module 100 can receive the light L1 from above, it can serve as a top-illuminated device. After the light L1 enters the photoelectric device module 100 from above, since the first reflectivity of the first reflective layer 120 is greater than the second reflectivity of the second reflective layer 160, the light L1 is easily reflected by the first reflective layer 120 and enters the photoelectric conversion layer 140 again, which helps the photoelectric conversion layer 140 absorb the light L1 again to enhance the external quantum efficiency (EQE) of the photoelectric device module 100. In more detail, the photoelectric device module 100 has a micro-cavity, that is, the space between the upper surface of the first reflective layer 120 and the lower surface of the second reflective layer 160. Therefore, the light L1 is reflected between the first reflective layer 120 and the second reflective layer 160, which are like two mirrors, increasing the light absorption amount of the photoelectric conversion layer 140 through the micro-cavity effect, thereby enhancing the EQE and photocurrent of the photoelectric device module 100. It is worth noting that the micro-cavity effect is affected by the thicknesses of the films between the first reflective layer 120 and the second reflective layer 160. By adjusting the thickness T4 of the photoelectric conversion layer 140, the thickness T2 of the first carrier transport layer 130, and the thickness T3 of the second carrier transport layer 150, the micro-cavity effect can be further optimized, thereby improving the light absorption capacity of the photoelectric conversion layer 140. The first carrier transport layer 130 can be used as an optical spacer to appropriately adjust the light field and effectively distribute photons into the photoelectric conversion layer 140, so that the reflected light can be absorbed and utilized again by the photoelectric conversion layer 140, thereby improving the EQE and photocurrent of the photoelectric device module 100. The wavelength range of the photoelectric response can be controlled by adjusting the optical-electrical field distribution to meet different product needs and application requirements. When the photoelectric conversion layer 140 contains materials that can respond to short-wave infrared (SWIR) light, the photoelectric device module 100 can be applied in the field of SWIR sensors. Although the absorption coefficients of these materials are usually low, the photoelectric device module 100 can still increase the absorbance of the photoelectric conversion layer 140 through the micro-cavity effect. When the thickness T4 of the photoelectric conversion layer 140 is small, the first reflective layer 120 can provide a micro-cavity effect to increase the absorbance of the photoelectric conversion layer 140.

In some embodiments, the substrate 110 includes glass, ceramic, silicon, plastic, polymers, or combinations thereof. In some embodiments, the substrate 110 is opaque. In some embodiments, the thickness T1 of the first reflective layer 120 is greater than or equal to 50 nm. For example, the thickness T1 is 50 nm to 500 nm, such as 50, 100, 150, 200, 250, 300, 350, 400, 450, or 500 nm. The thickness T1 of the first reflective layer 120 does not affect the photoelectric conversion efficiency, so it can be adjusted according to design requirements. In some embodiments, the first reflective layer 120 is a conductive layer, and it includes, for example, silver, aluminum, copper, gold, titanium, tungsten, molybdenum, titanium nitride, or combinations thereof. If a silver layer is used as the first reflective layer 120, when the light L1 with a wavelength greater than 600 nm enters the silver layer from the first carrier transport layer 130, a phenomenon close to total internal reflection may occur, thereby increasing the absorbance of the photoelectric conversion layer 140. The wavelength of the light L1 is, for example, 600 nm to 2600 nm.

Please continue to refer to FIG. 1. In some embodiments, the thickness T2 of the first carrier transport layer 130 and the thickness T3 of the second carrier transport layer 150 are respectively between 10 nm and 100 nm, such as 10, 20, 30, 40, 50, 60, 70, 80, 90, or 100 nm. The first carrier transport layer 130 has carrier transport capability and can be used as an optical spacer to appropriately adjust the light field and effectively distribute photons into the photoelectric conversion layer 140, so that the reflected light can be absorbed and utilized again by the photoelectric conversion layer 140, thereby improving the EQE and photocurrent of the photoelectric device module 100. When the thickness T2 of the first carrier transport layer 130 increases, the EQE of the photoelectric device module 100 also increases accordingly.

Please continue to refer to FIG. 1. The materials of the first carrier transport layer 130 and the second carrier transport layer 150 are different. In some embodiments, among the first carrier transport layer 130 and the second carrier transport layer 150, one is an electron transport layer, and the other is a hole transport layer. For example, the first carrier transport layer 130 is an electron transport layer, and the second carrier transport layer 150 is a hole transport layer. For example, the first carrier transport layer 130 is a hole transport layer, and the second carrier transport layer 150 is an electron transport layer. In some embodiments, the first carrier transport layer 130 and the second carrier transport layer 150 respectively include a metal oxide or an organic material (e.g., organic small molecules, polymers, or cross-linkable molecules). In some embodiments, the electron transport layer includes aluminum zinc oxide, zinc oxide (ZnO), titanium oxide (such as titanium dioxide), tin oxide (such as tin dioxide), polyelectrolyte, 4,7-diphenyl-1,10-phenanthroline, (BPhen), or combinations thereof. In some embodiments, the hole transport layer includes molybdenum trioxide (MoO₃), nickel monoxide (NiO), tungsten trioxide (WO₃), PEDOT:

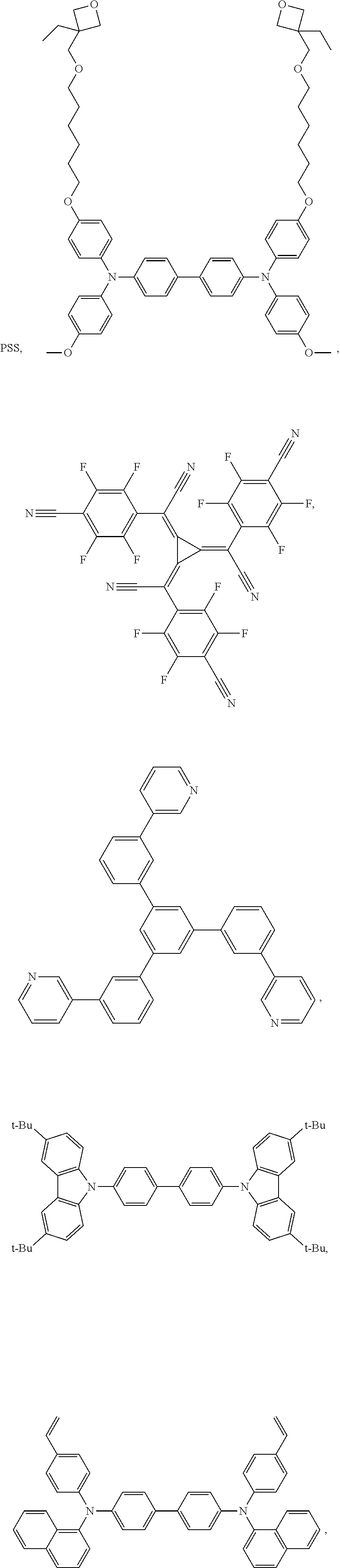 [SMILES: CCC1(COCCCCCCOc2ccc(N(c3ccc(OC)cc3)c3ccc(-c4ccc(N(c5ccc(OC)cc5)c5ccc(OCCCCCCOCC6(CC)COC6)cc5)cc4)cc3)cc2)COC1 ; N#CC(=C1C(=C(C#N)c2c(F)c(F)c(C#N)c(F)c2F)C1=C(C#N)c1c(F)c(F)c(C#N)c(F)c1F)c1c(F)c(F)c(C#N)c(F)c1F ; c1cncc(-c2cccc(-c3cc(-c4cccc(-c5cccnc5)c4)cc(-c4cccc(-c5cccnc5)c4)c3)c2)c1 ; CC(C)(C)c1ccc2c(c1)c1cc(C(C)(C)C)ccc1n2-c1ccc(-c2ccc(-n3c4ccc(C(C)(C)C)cc4c4cc(C(C)(C)C)ccc43)cc2)cc1 ; C=Cc1ccc(N(c2ccc(-c3ccc(N(c4ccc(C=C)cc4)c4cccc5ccccc45)cc3)cc2)c2cccc3ccccc23)cc1]

bathocuproine (BCP), buckminsterfullerene (C60), polyethylenimine (PEI), ethoxylated polyethylenimine (PEIE), or combinations thereof. The PEI can have the following structure

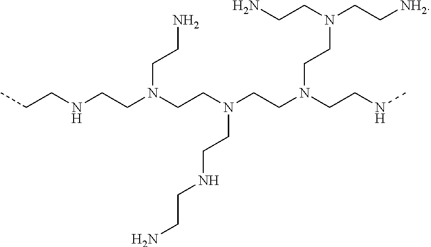

PEIE can have the following structure

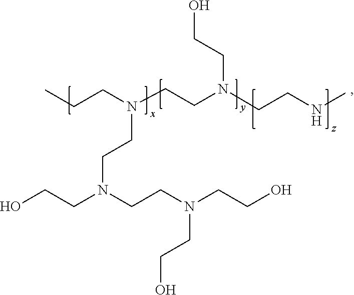

where x, y, and z are mole fractions, and the sum of x, y, and z is 1. In other embodiments, the first carrier transport layer 130 disposed between the first reflective layer 120 and the photoelectric conversion layer 140 is omitted, so that the photoelectric conversion layer 140 is disposed on the first reflective layer 120 and directly contacts the first reflective layer 120. In other embodiments, the second carrier transport layer 150 disposed between the photoelectric conversion layer 140 and the second reflective layer 160 is omitted, so that the second reflective layer 160 is disposed on the photoelectric conversion layer 140 and directly contacts the photoelectric conversion layer 140.

In some embodiments, the photoelectric conversion layer 140 includes a material that can respond to short-wave infrared (SWIR) light. More specifically, the photoelectric conversion layer 140 can respond to light with a wavelength greater than or equal to 1000 nm. For example, the photoelectric conversion layer 140 can detect light with a wavelength between 1000 nm and 5500 nm, such as 1000, 1050, 1500, 2000, 2500, 3000, 3500, 4000, 4500, 5000, or 5500 nm. In some embodiments, the photoelectric conversion layer 140 has an optical energy gap of less than or equal to 1.24 eV, such as 0.84, 0.94, 1.04, 1.14, or 1.24 eV. In some embodiments, the thickness T4 of the photoelectric conversion layer 140 is 135 nm to 500 nm, such as 135, 140, 160, 180, 200, 220, 240, 260, 280, 300, 320, 340, 360, 380, 400, 420, 440, 460, 480, or 500 nm. When the thickness T4 is less than 135 nm, the micro-cavity effect between the first reflective layer 120 and the second reflective layer 160 may be weak. When the thickness T4 is more than 500 nm, the EQE of the photoelectric device module 100 may decrease due to the limitation of the carrier transfer capability of the photoelectric conversion layer 140. In some embodiments, the photoelectric conversion layer 140 is formed by spin coating.

In some embodiments, the photoelectric conversion layer 140 includes an organic semiconductor, an inorganic semiconductor, a quantum dot, perovskite, or combinations thereof. In some embodiments, the quantum dot includes CdSe, CdZnS, CdSeS, CdS, ZnSe, InP, InS, CdTe, CulnS₂, CulnZnS, ZnS, PbS, PbSe, AgInS₂, Ag₂Te, InAs, Cd₃As₂, AgBiS₂, InAs/InP, InGaP, or combination thereof. In some embodiments, the perovskite has the following general formula: ABX₃, where A is an organic cation, B is a metal cation, and X is a halogen anion. In some embodiments, the perovskite includes CH₃NH₃Pbl₃, CH₃NH₃PbBrs, (MeNH₃)PbBr₃, Cs₂Sn₃I₆, Ag₃BiI₆, (CH₃NH₃)₃Bi₂Cl₉, Cs₂SnI₅Br, Cs₂TiBr₆, or combinations thereof. In some embodiments, the organic semiconductor includes one or more P-type organic semiconductors and one or more N-type organic semiconductors. The P-type organic semiconductor can be a conjugated polymer, and the N-type organic semiconductor can be a non-fullerene material or a fullerene material. For example, the P-type organic semiconductors include:

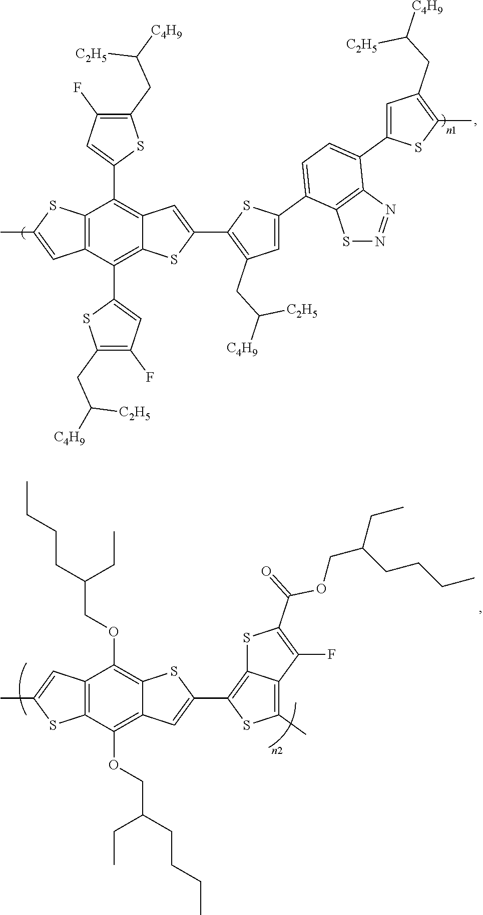

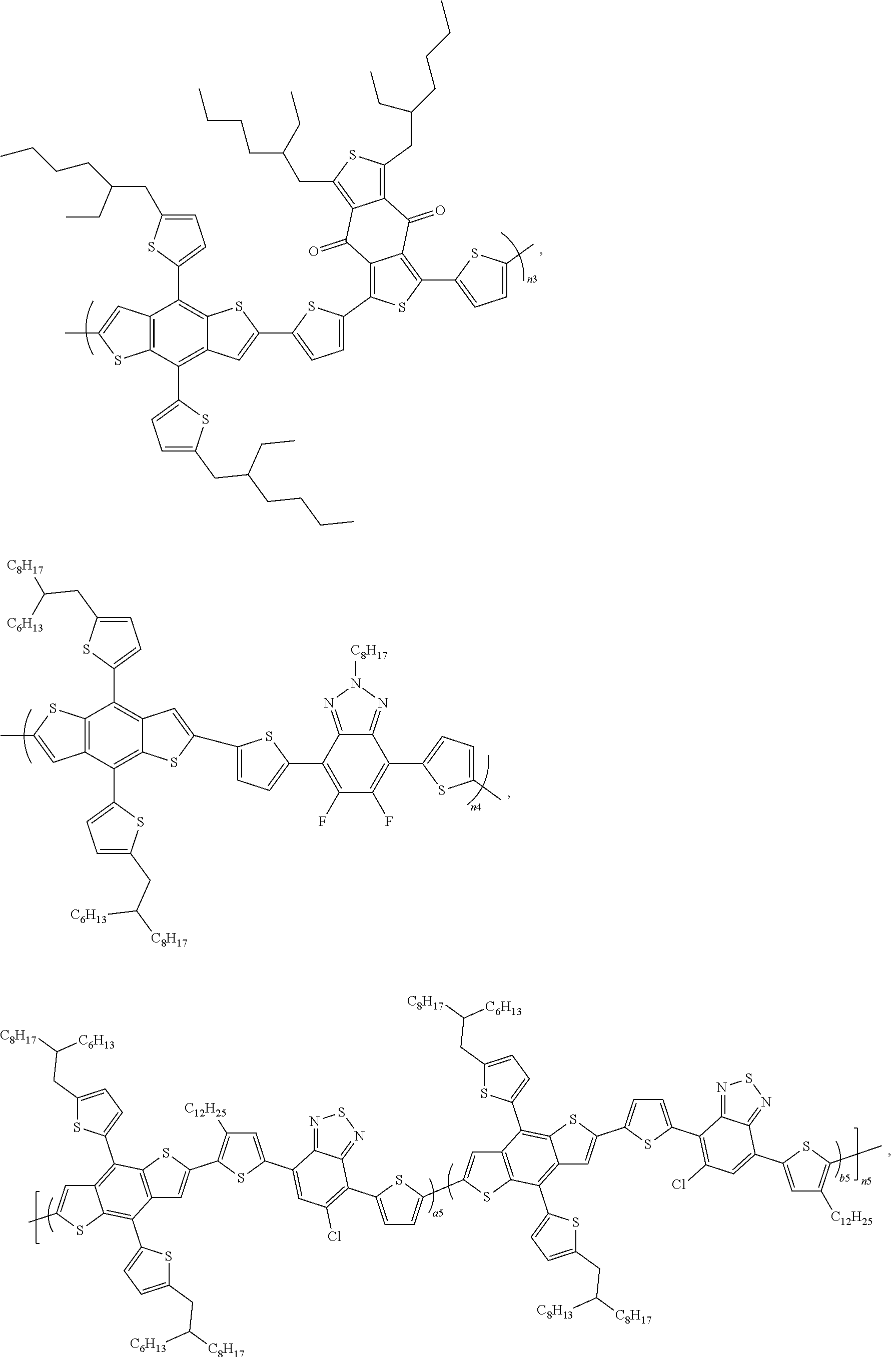

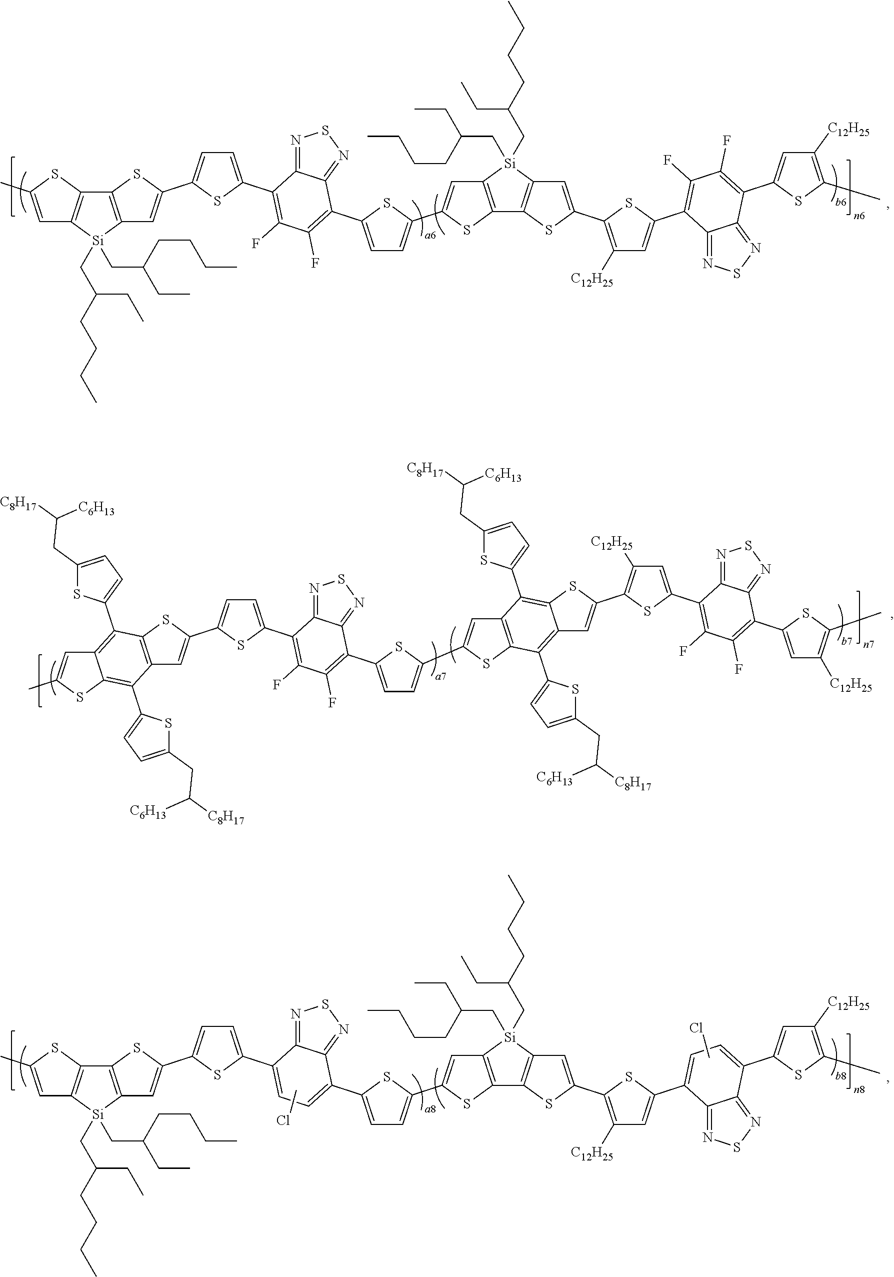

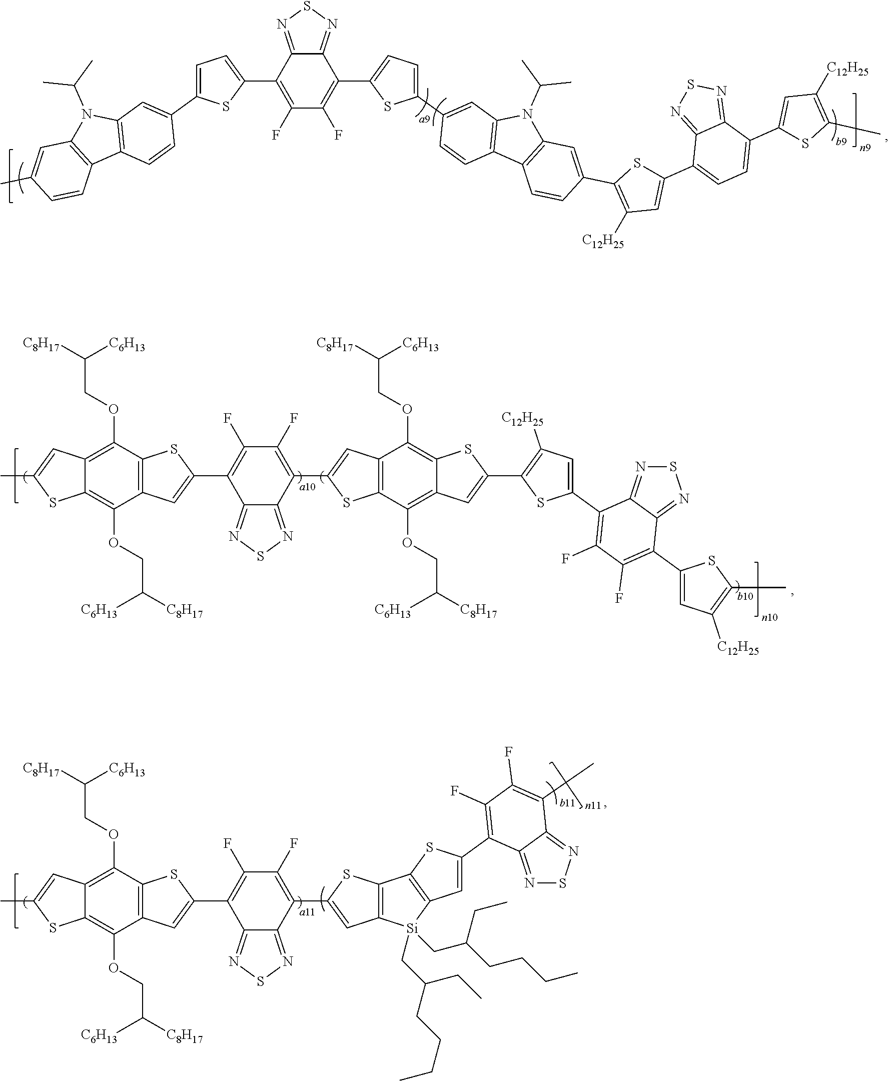

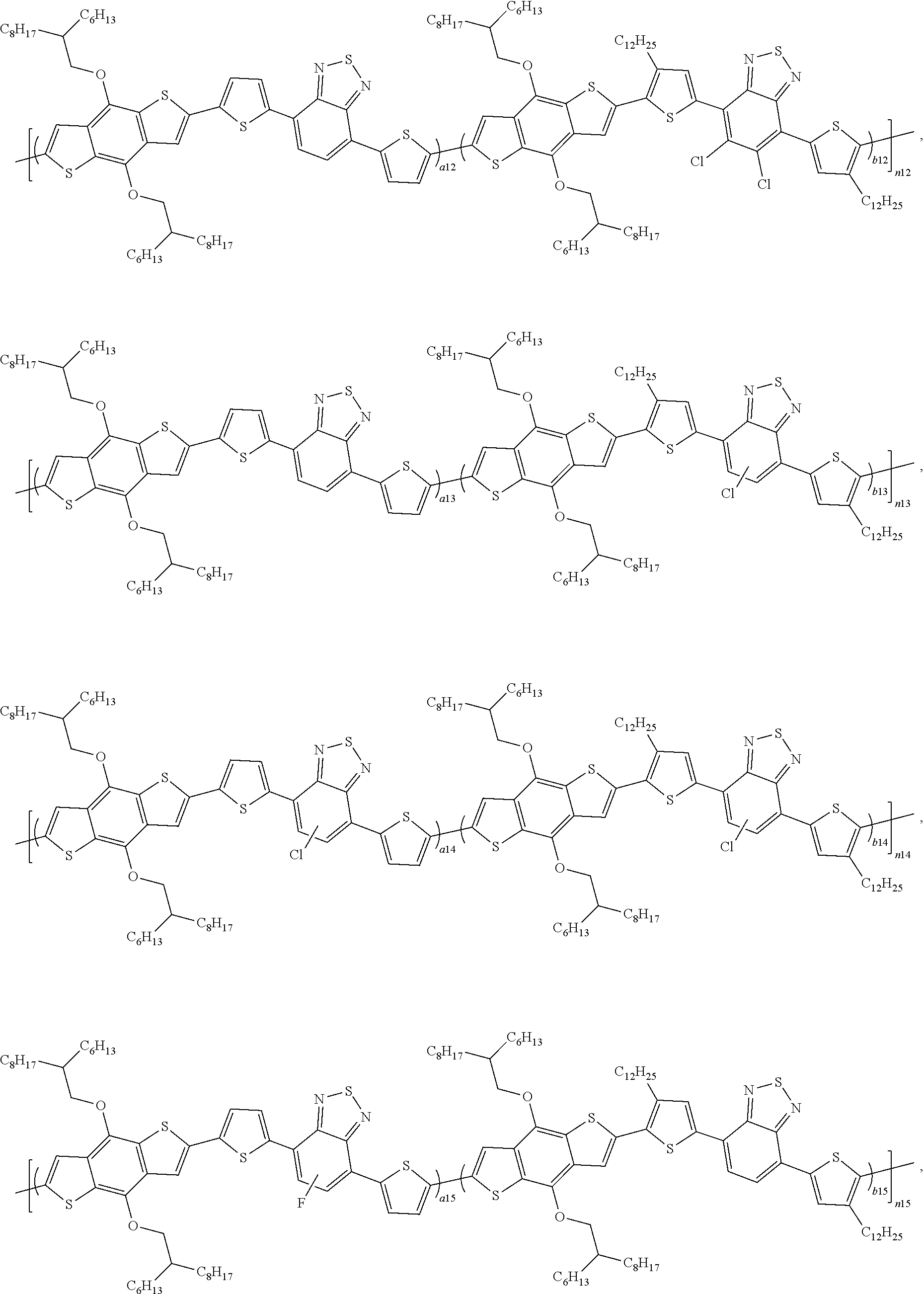

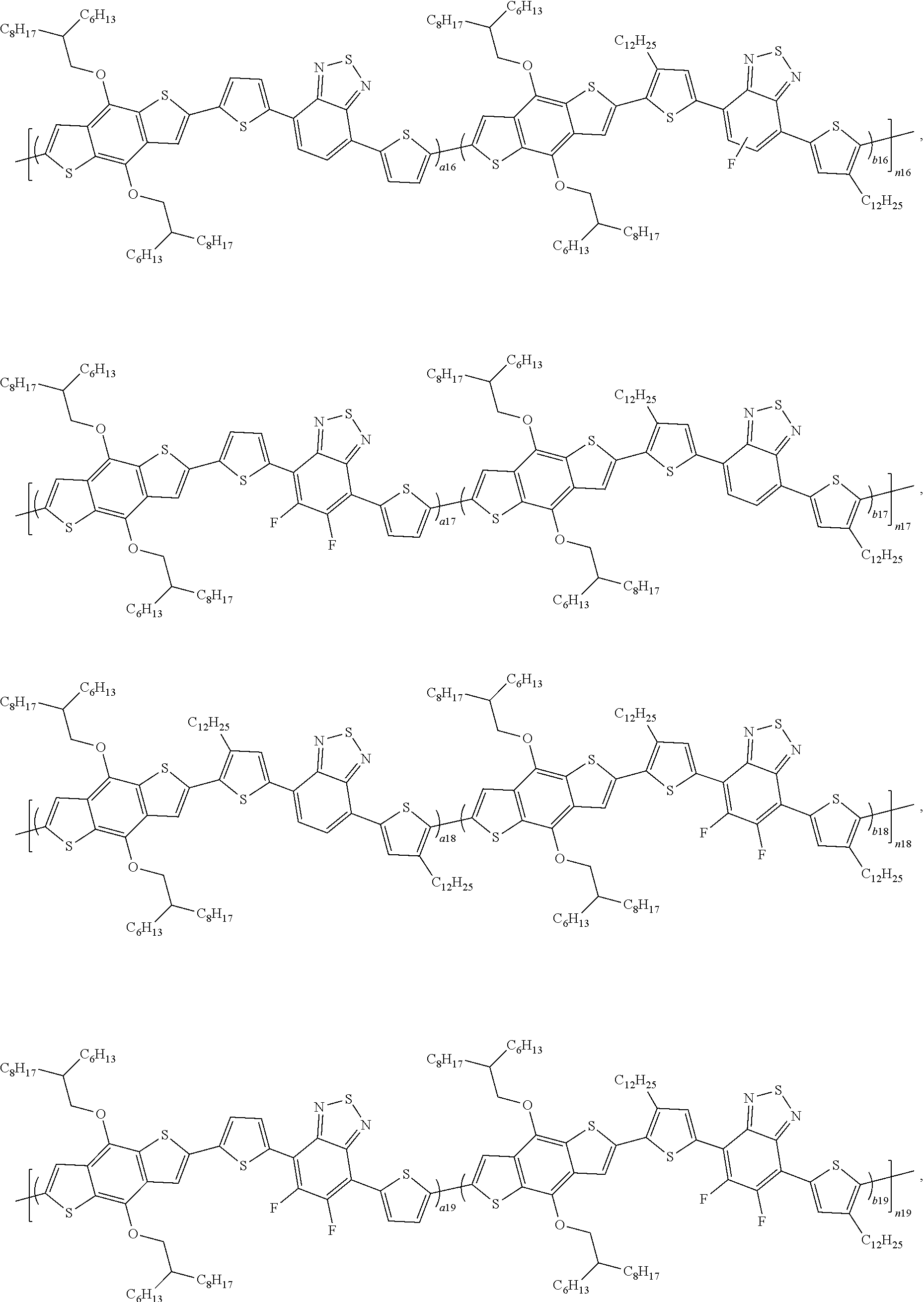

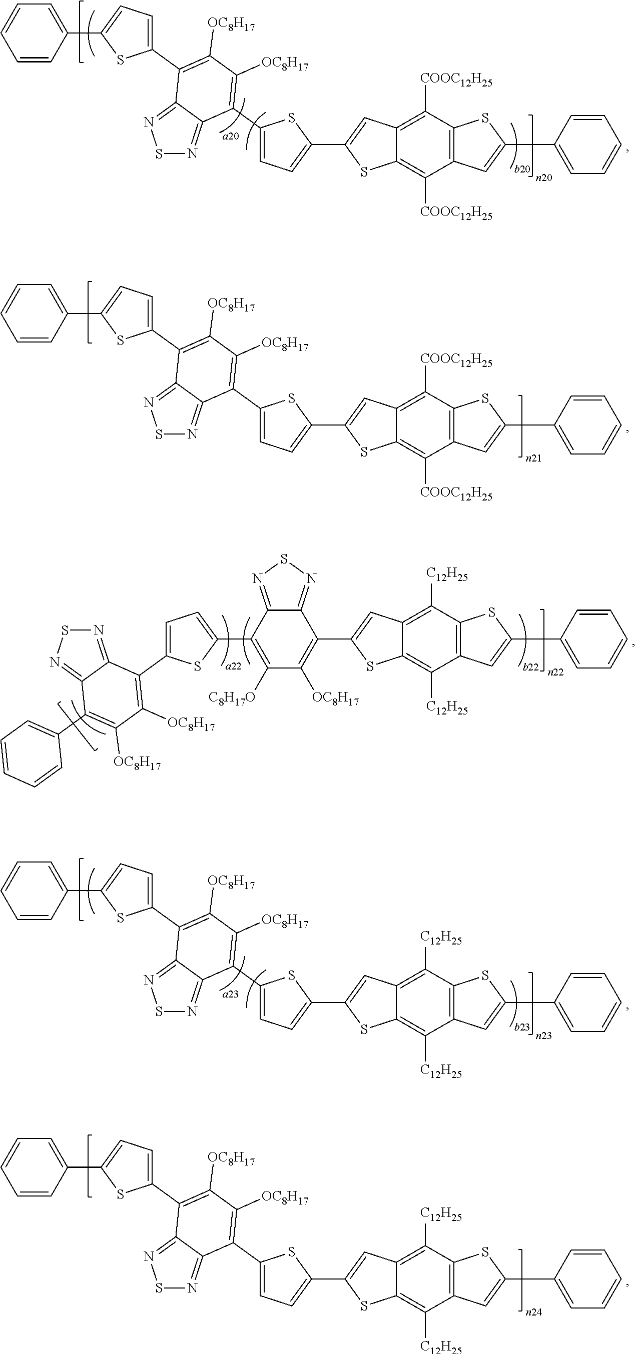

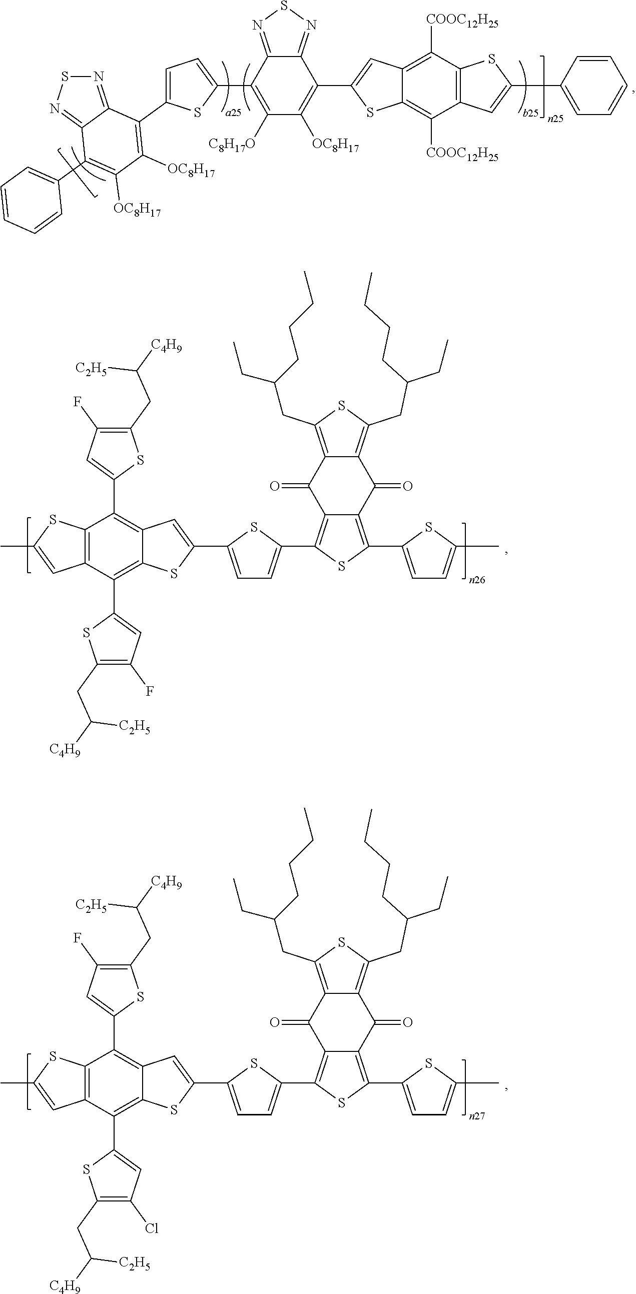

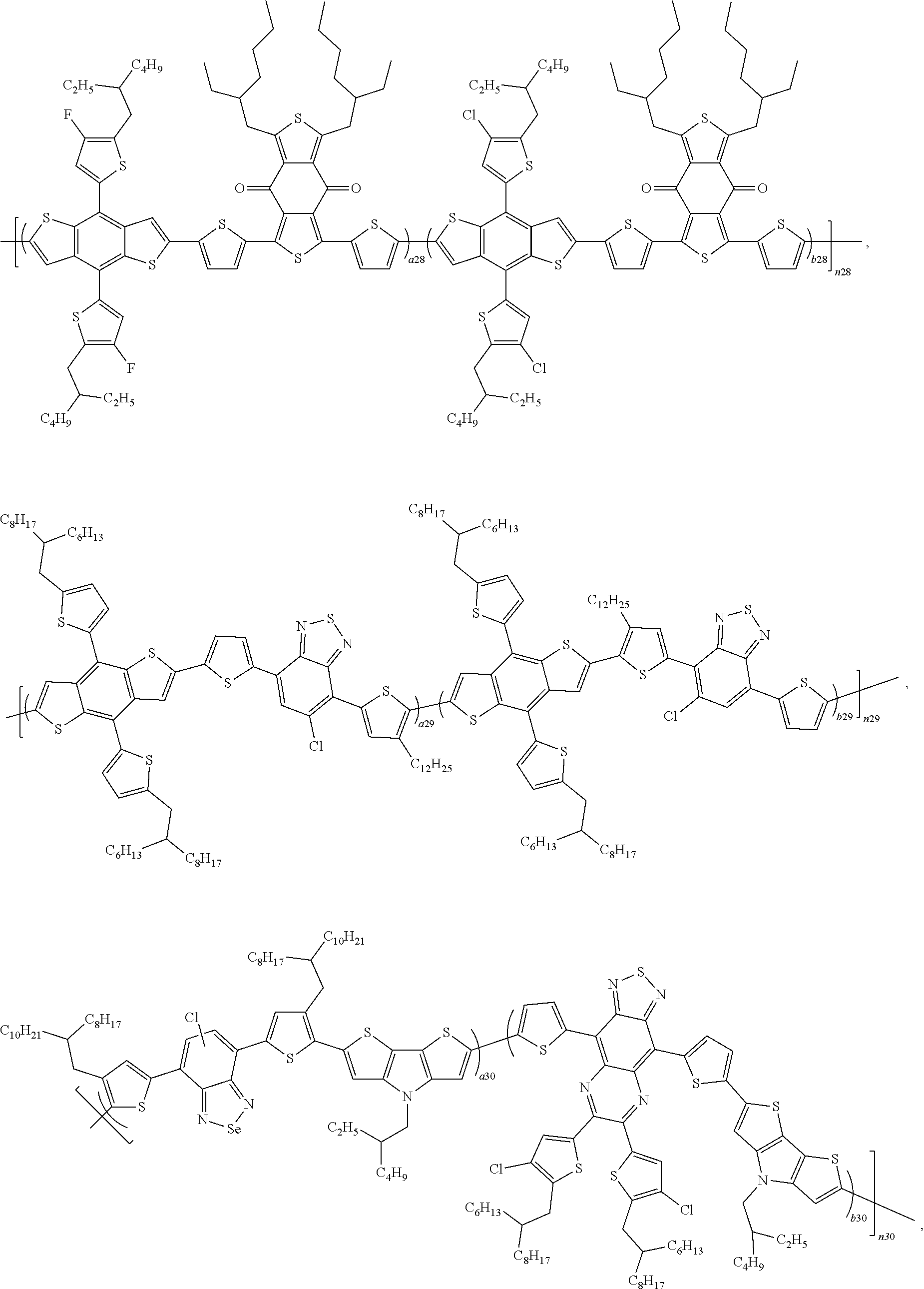

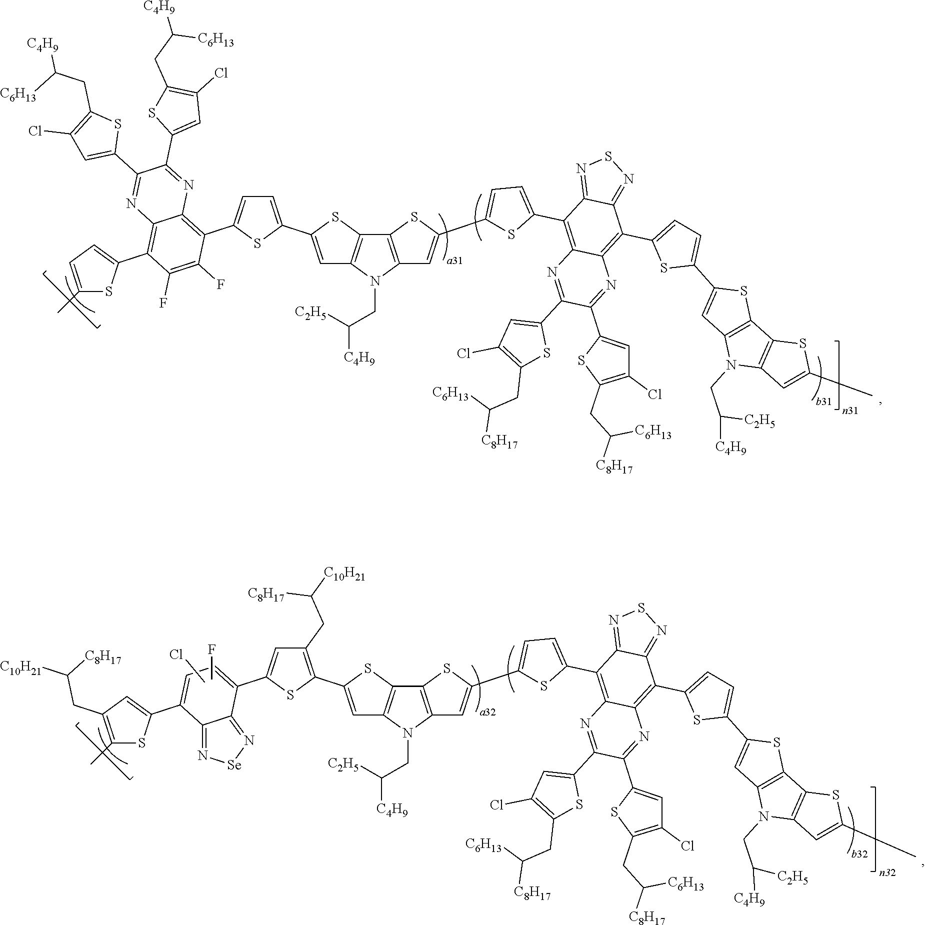

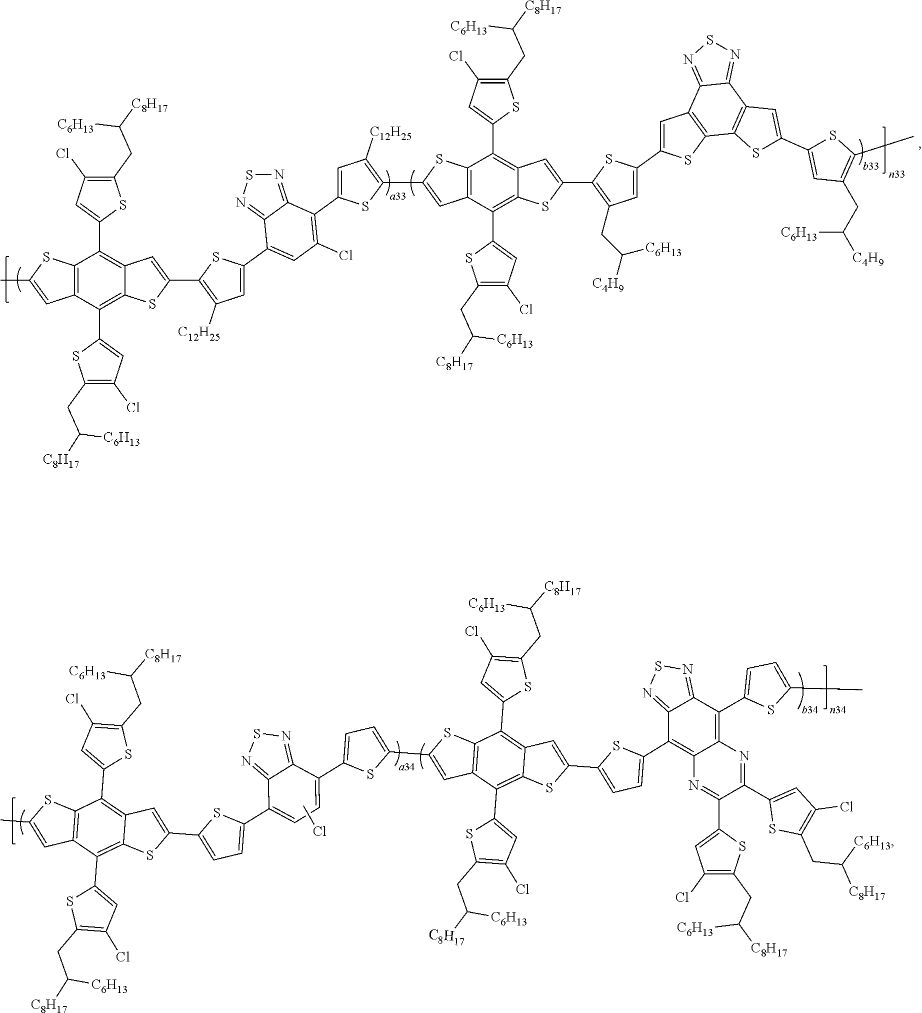

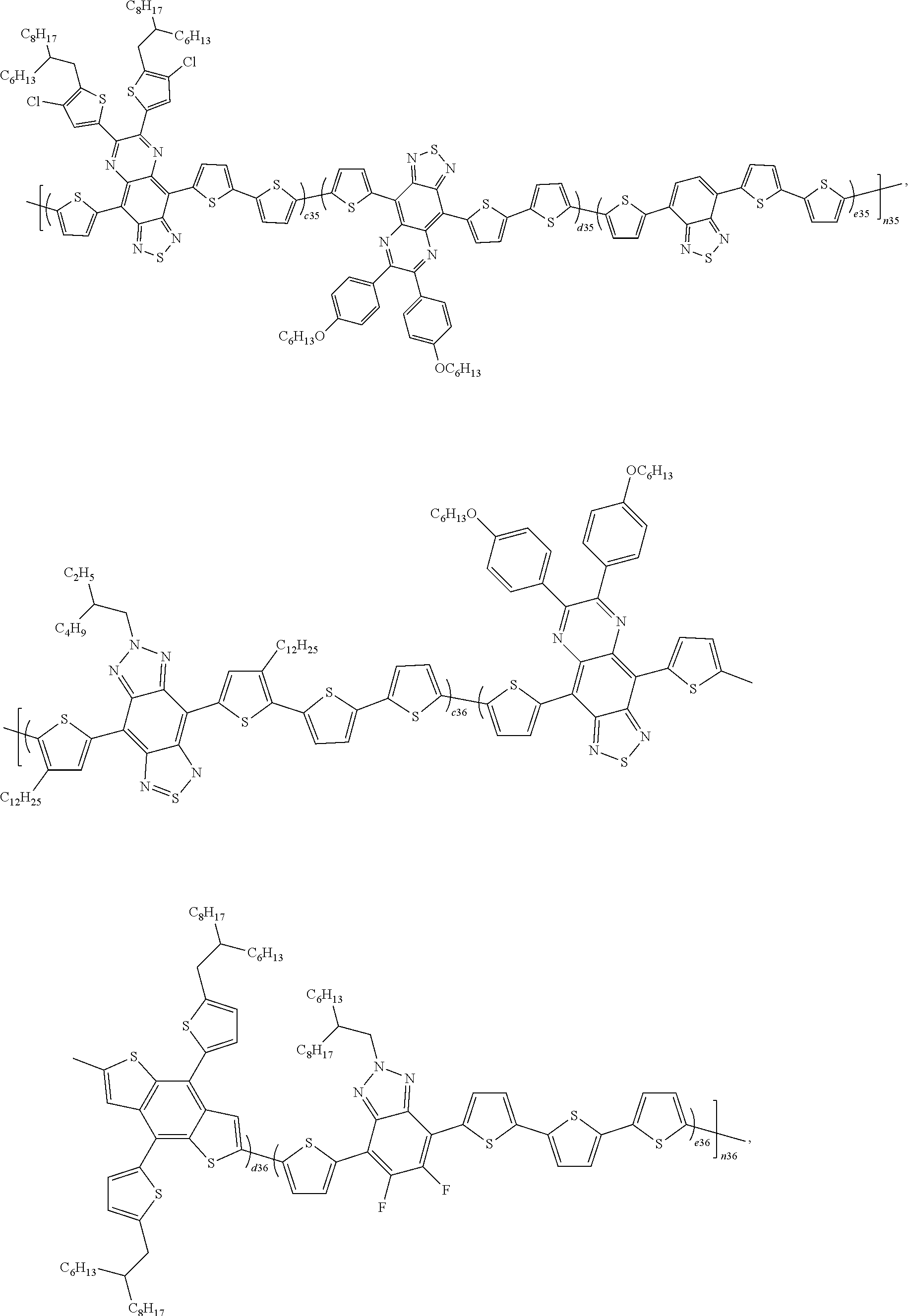

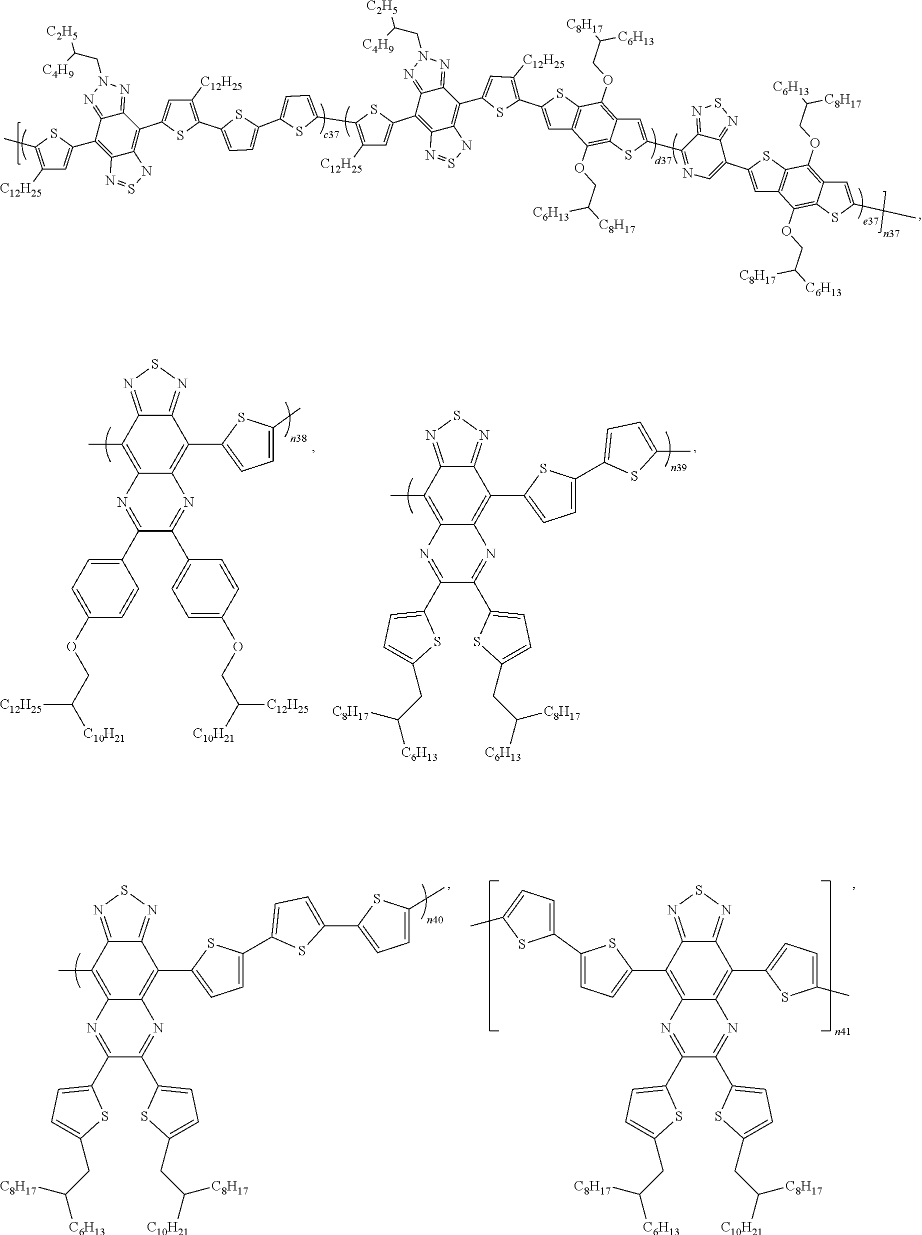

or combinations thereof. In the above P-type organic semiconductors, n1 to n41 are each independently a positive integer from 1 to 1000. a5-a20, a22, a23, a25, a28-a34, b5-b20, b22, b23, b25, b28-b34, c35-c37, d35-d37, and e35-e37 respectively represent a mole fraction and respectively are greater than 0 and less than 1. In each P-type organic semiconductor, the sum of all molar fractions is 1. For example, the N-type organic semiconductors include:

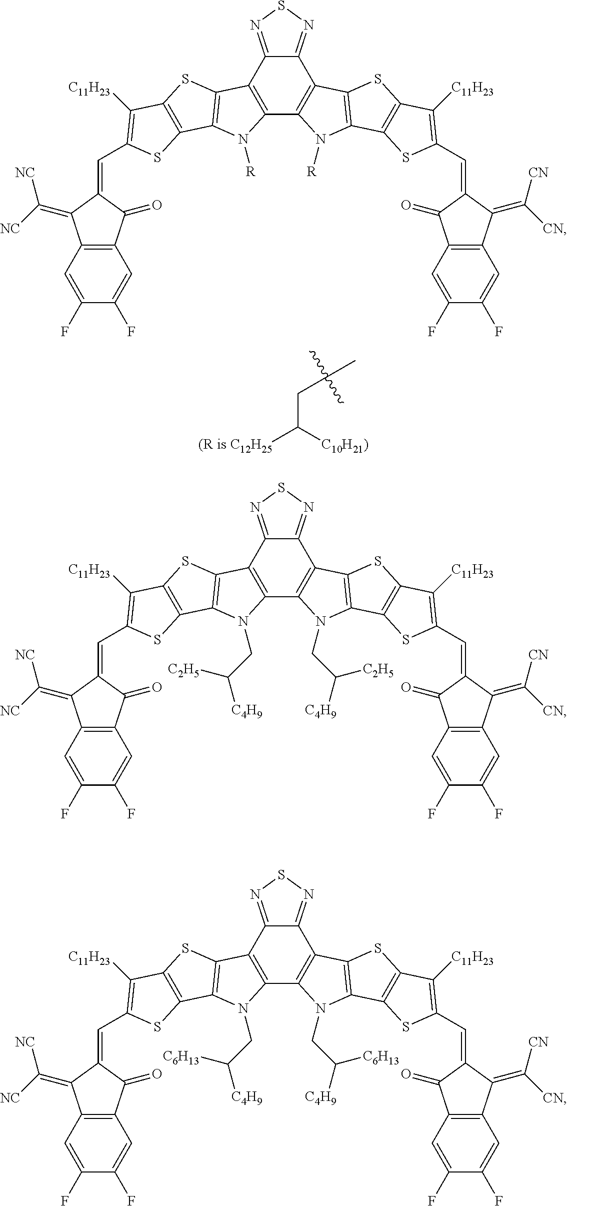

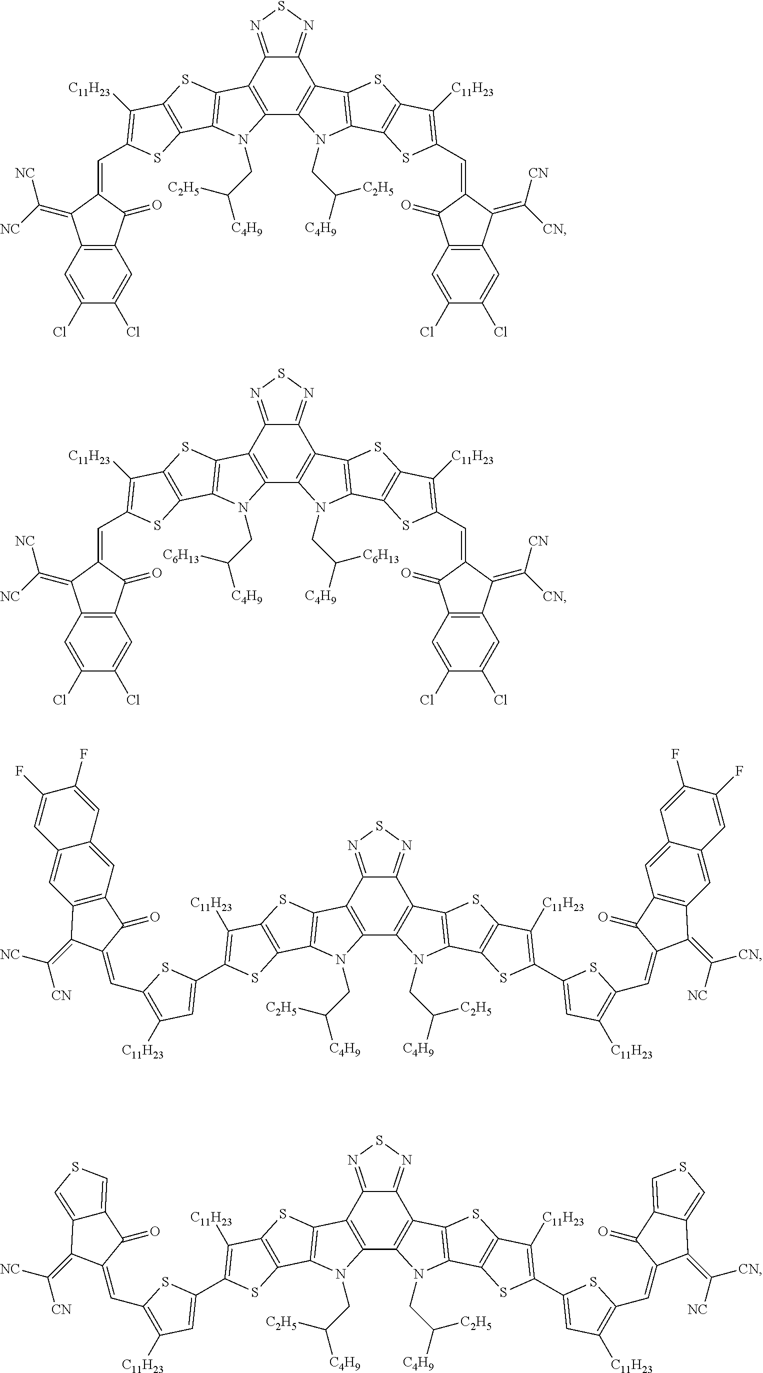

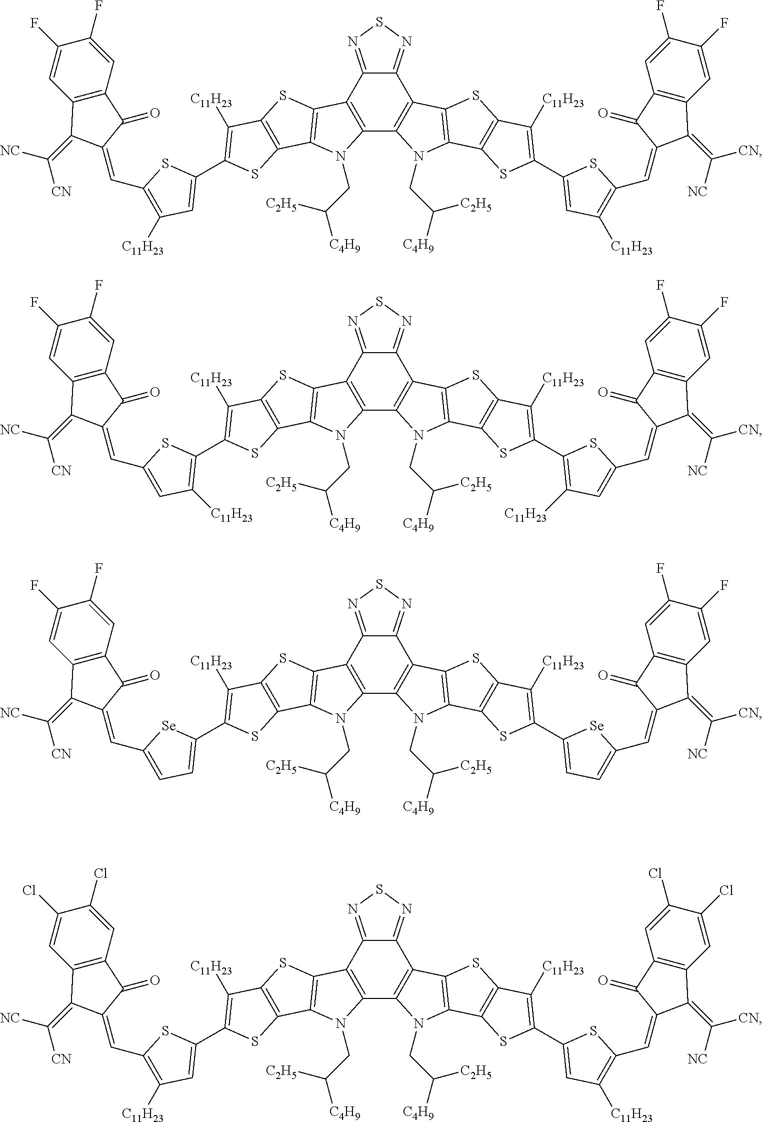

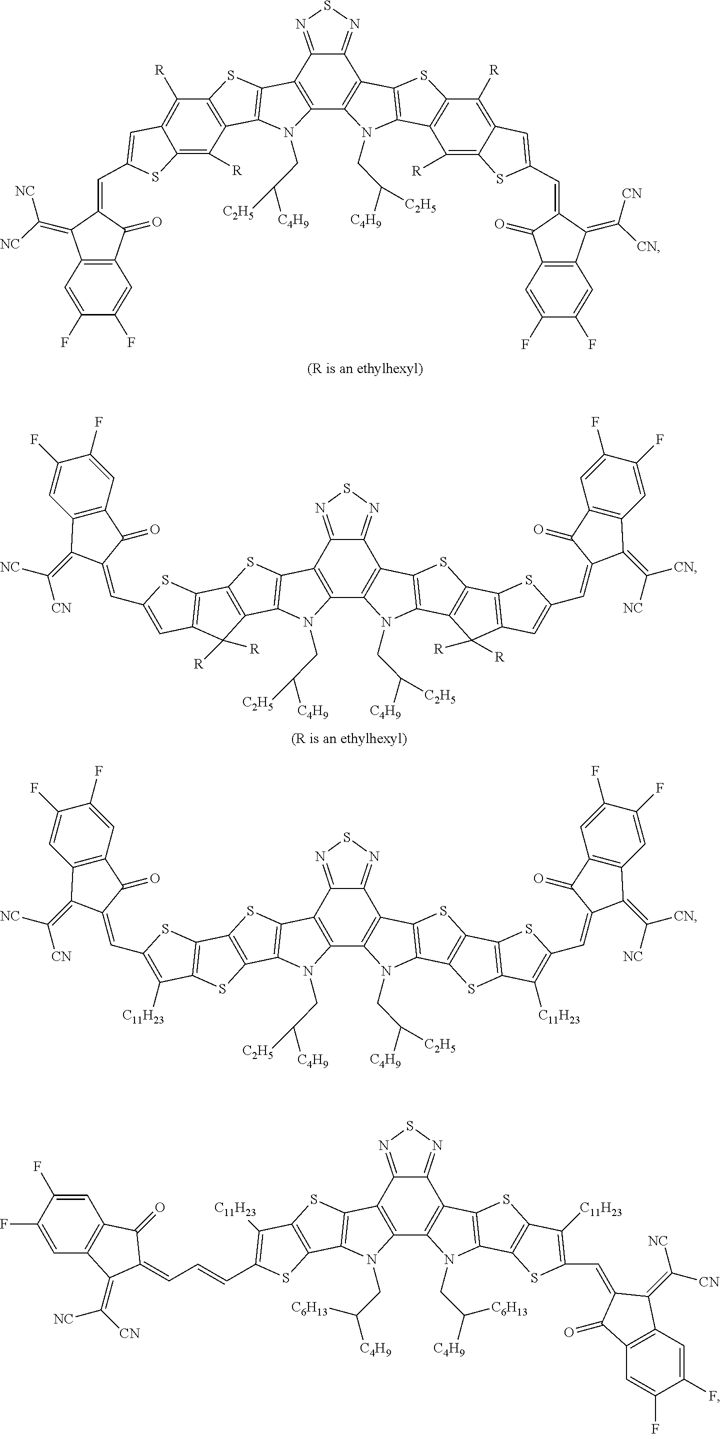

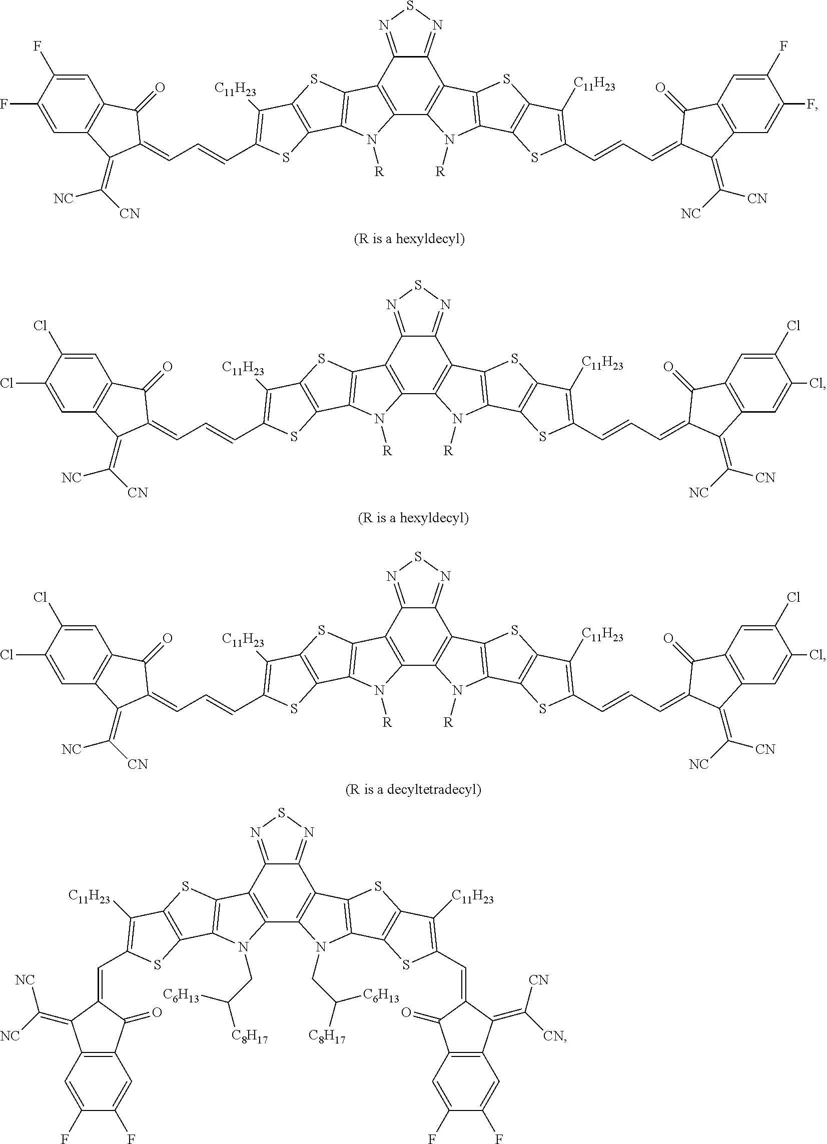

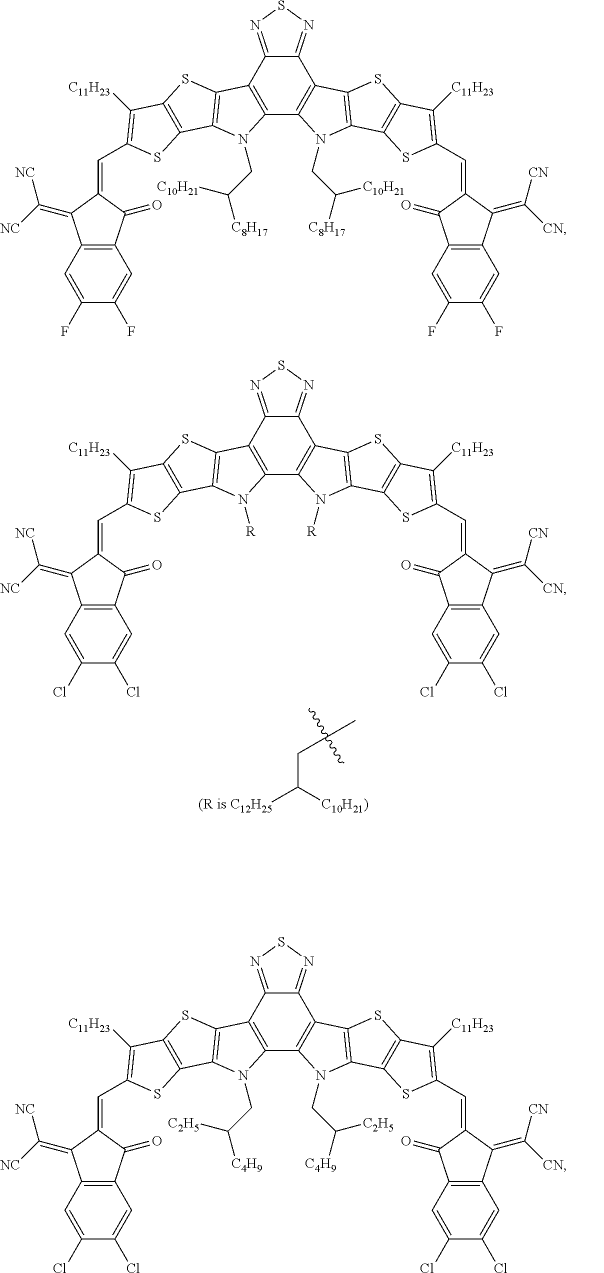

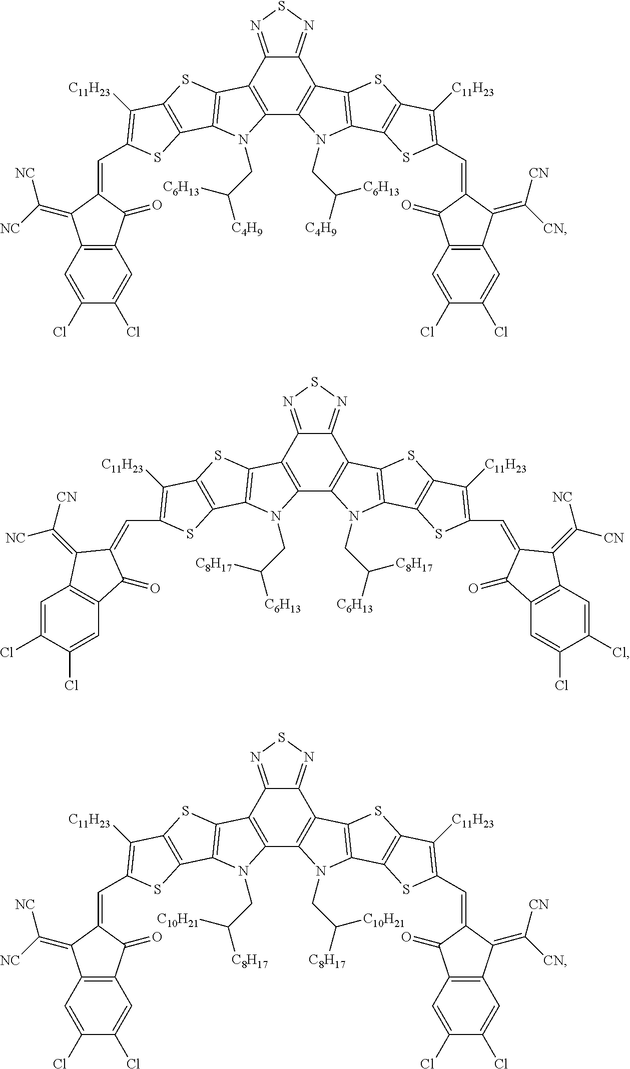

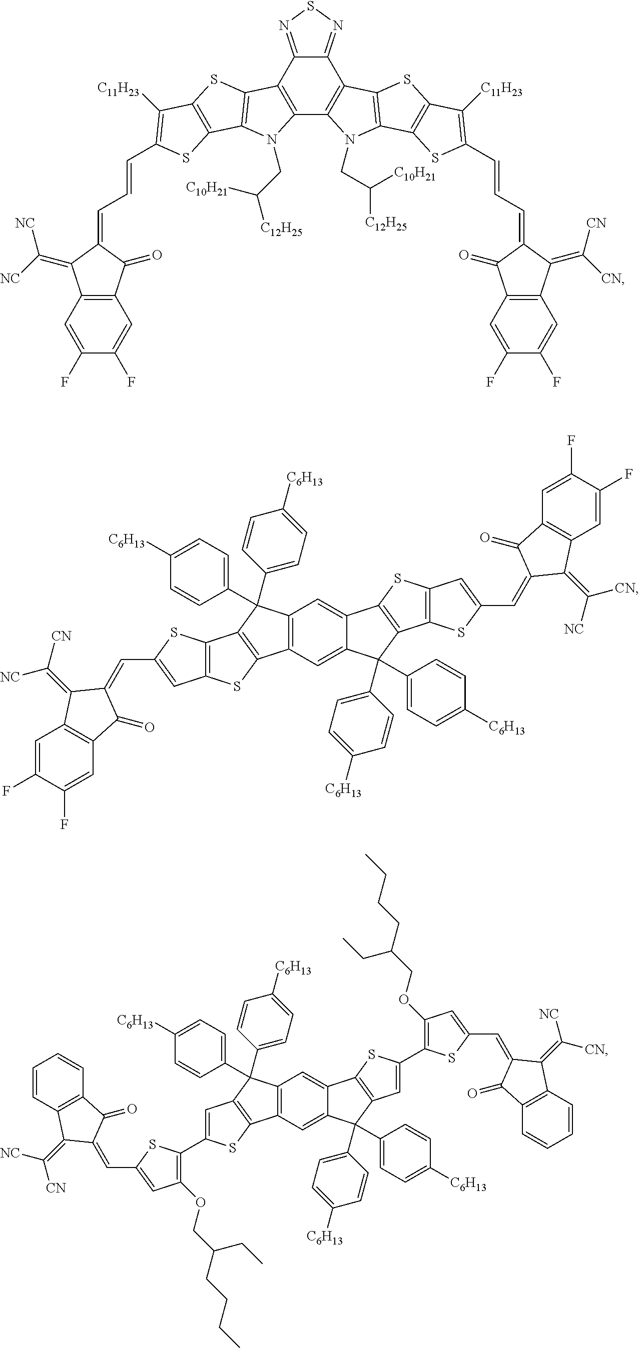

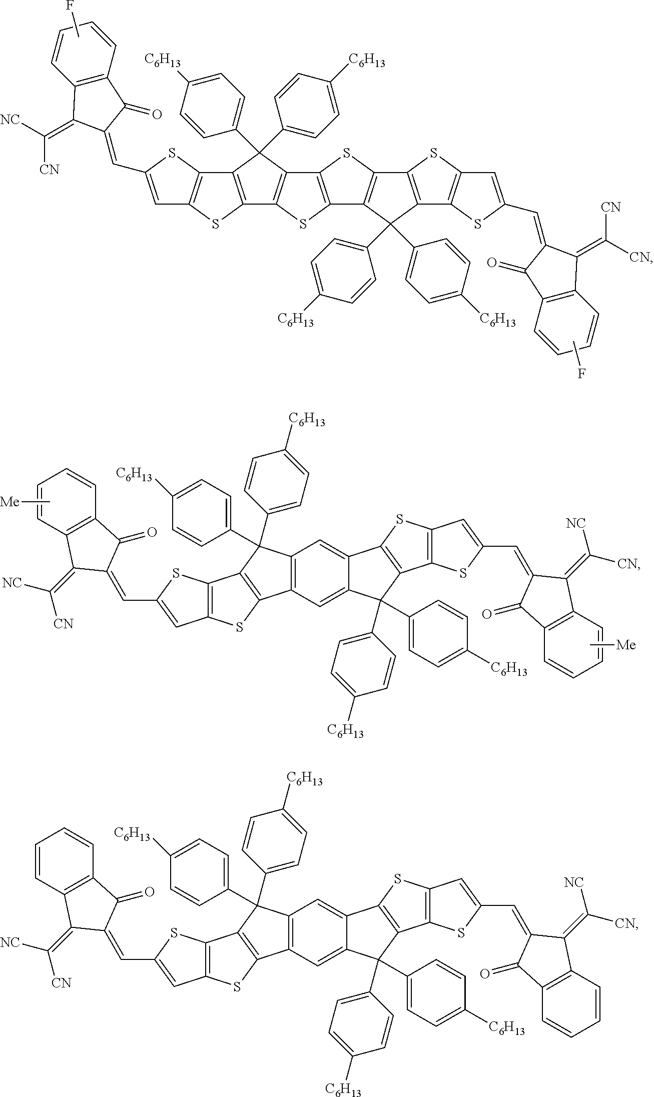

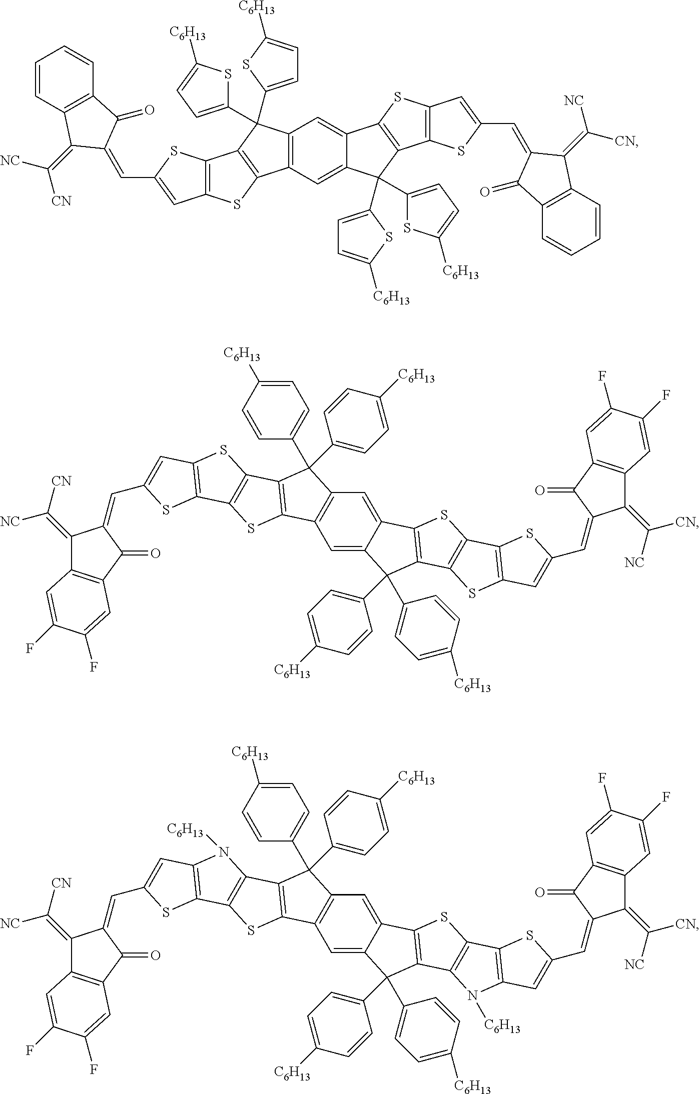

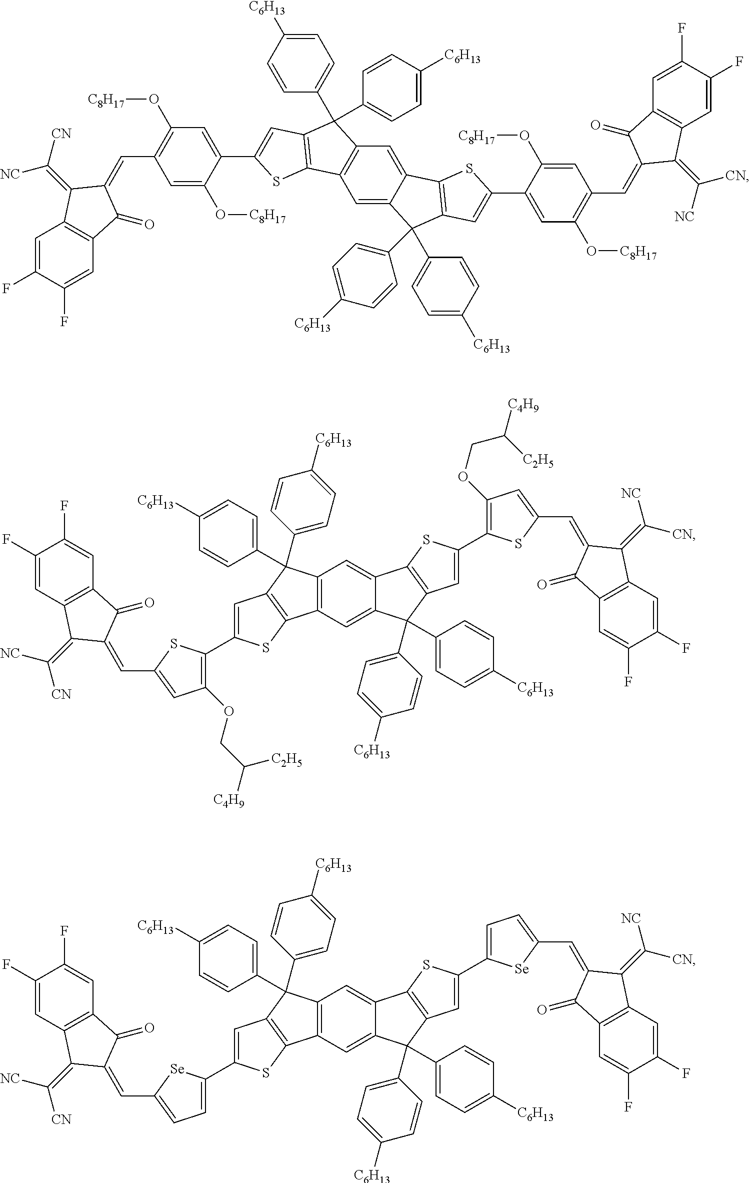

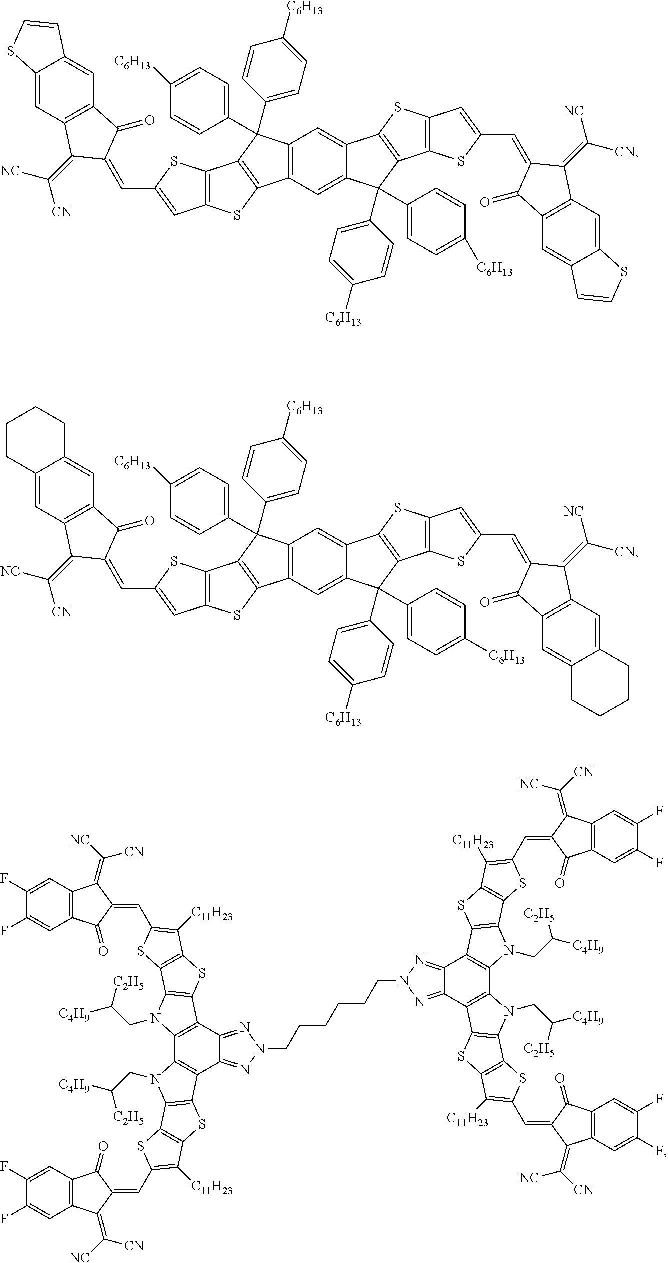

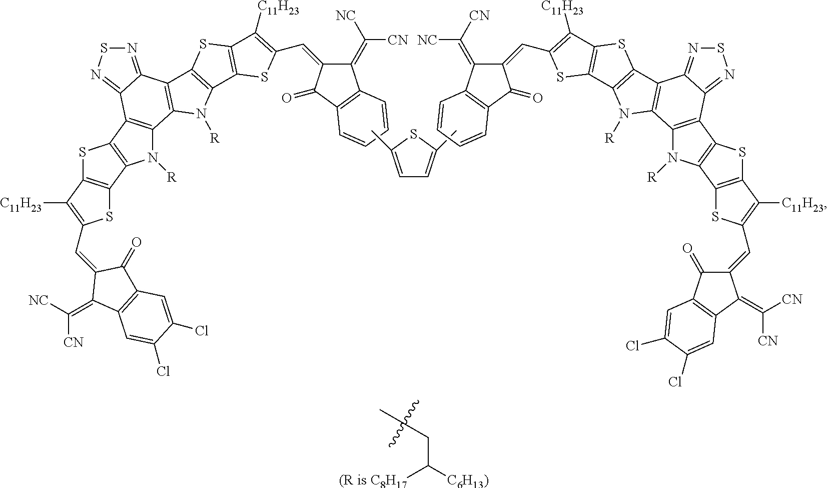

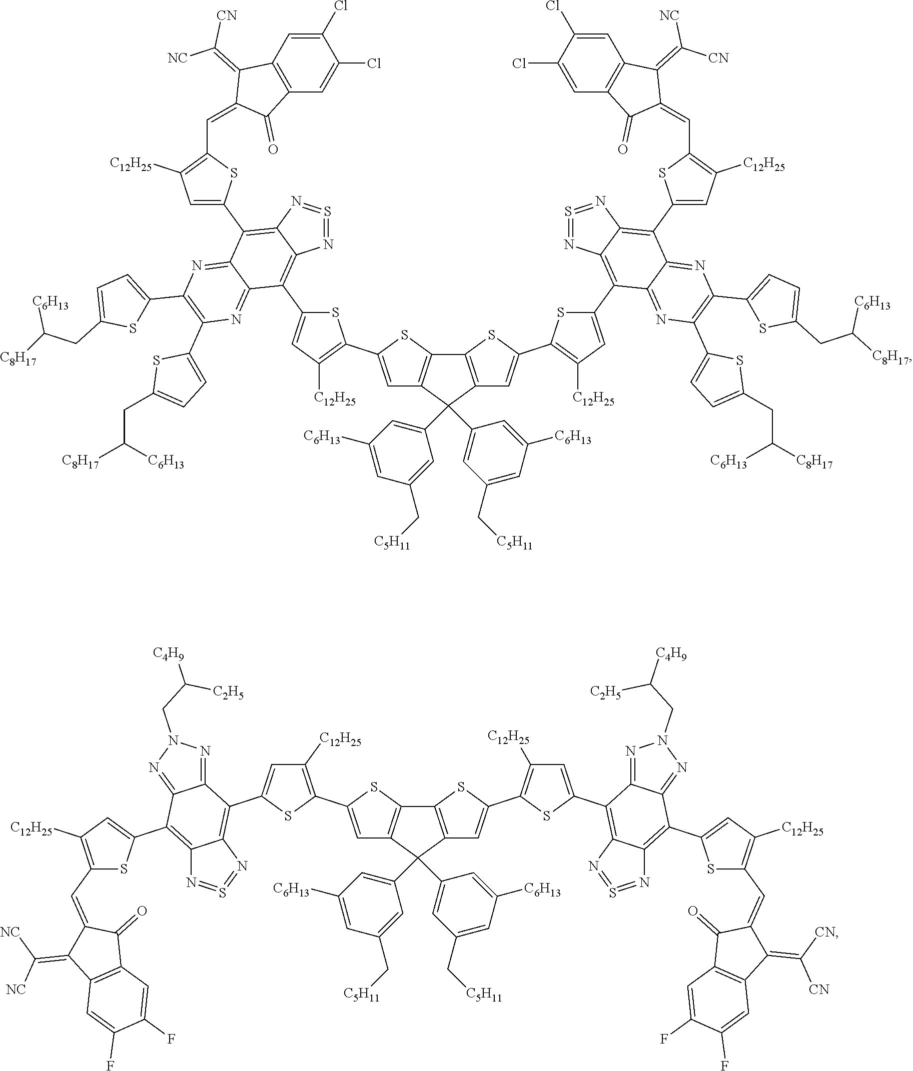

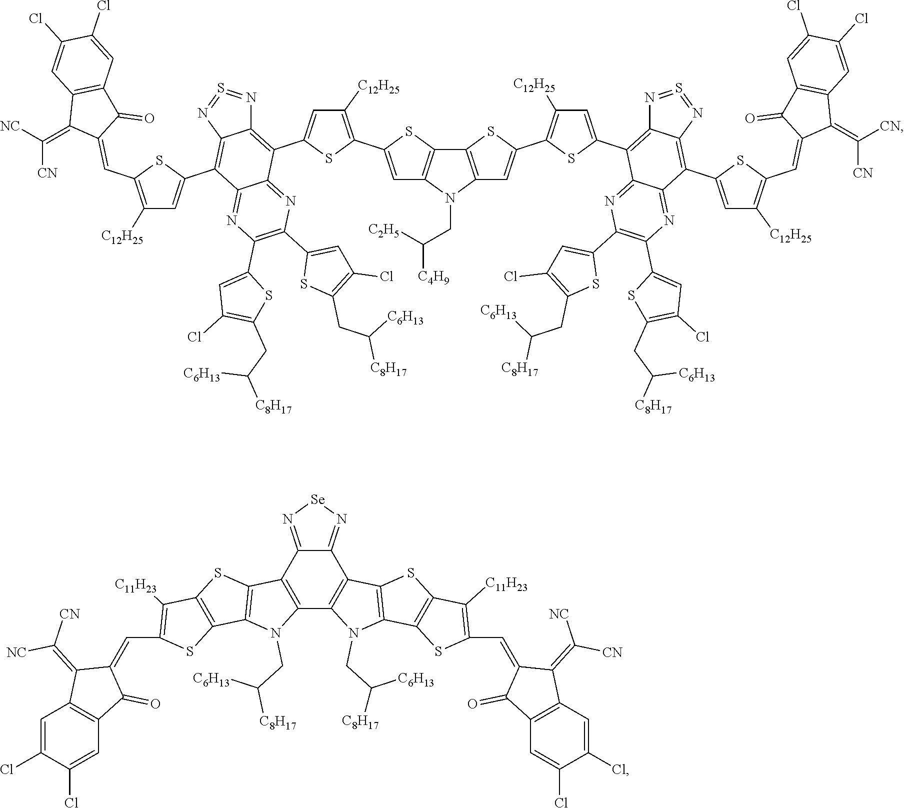

or combinations thereof.

In some embodiments, the second reflective layer 160 is a light-transmitting conductive layer. In some embodiments, the thickness T5 of the second reflective layer 160 is 90 nm to 200 nm, such as 90, 100, 120, 140, 160, 180, or 200 nm. When the thickness T5 falls within the above range, the photoelectric device module 100 can still receive sufficient light for photoelectric conversion. In some embodiments, the second reflective layer 160 includes a transparent conductive oxide, a transparent conductive polymer, silver nanowires, a metal-containing layer with a thickness less than or equal to 15 nm, or combinations thereof. The TCO includes indium zinc oxide (IZO), indium gallium oxide (IGO), indium gallium zinc oxide (IGZO), indium tin zinc oxide (ITZO), indium tin oxide (ITO), zinc tin oxide (ZTO), aluminum zinc oxide (AZO) or combinations thereof. The transparent conductive polymer includes poly(3,4-ethylenedioxythiophene) polystyrene sulfonate (PEDOT:PSS), polyaniline, polyfluorene, polypyrrole, polythiophene, polycarbazole, or combinations thereof. The metal-containing layer may include a metal layer with a thickness less than or equal to 15 nm, such as a silver layer, a gold layer, an aluminum layer, a copper layer, or combinations thereof.

The following describes the features of the present disclosure more specifically with reference to examples. Although the following examples are described, the materials, their amounts and ratios, processing details, processing procedures, etc., may be appropriately varied without exceeding the scope of the present disclosure. Accordingly, the present disclosure should not be interpreted restrictively by the examples described below.

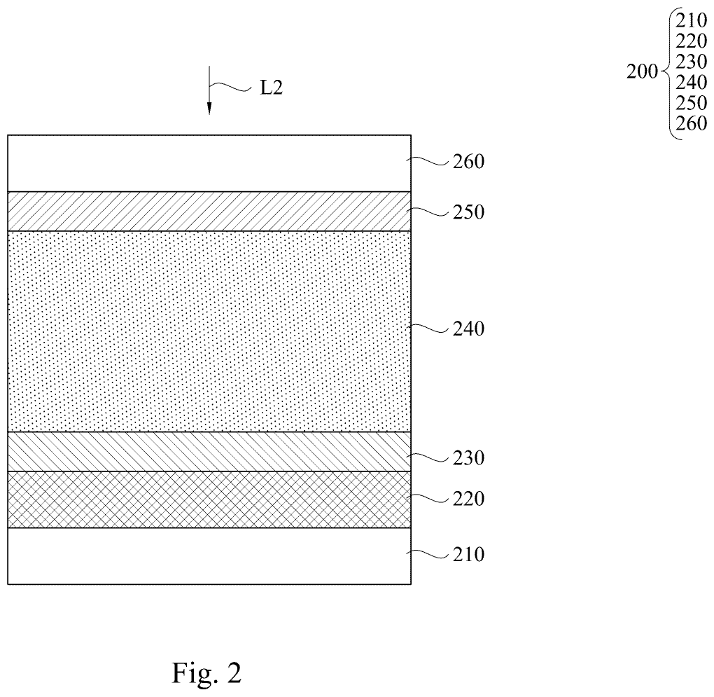

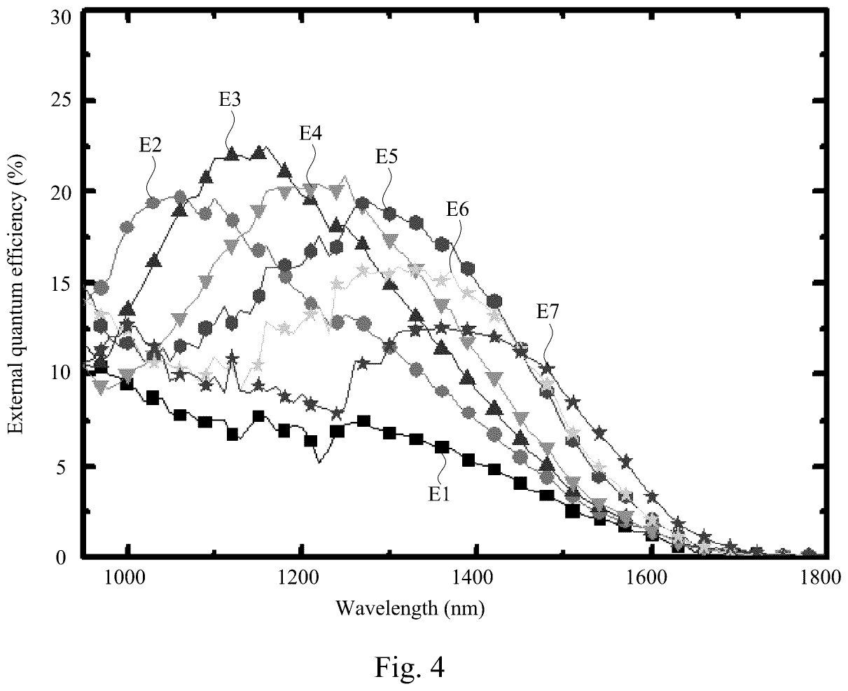

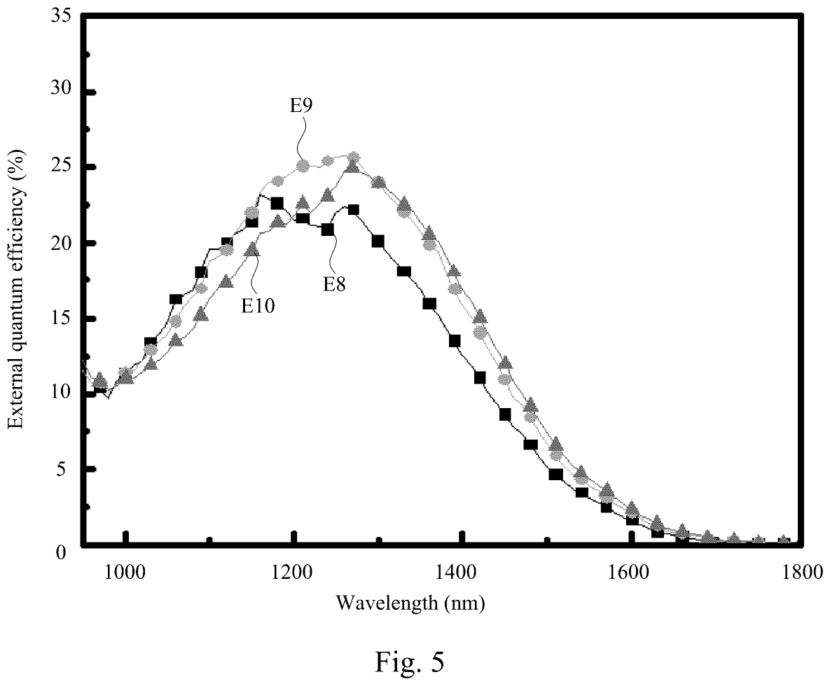

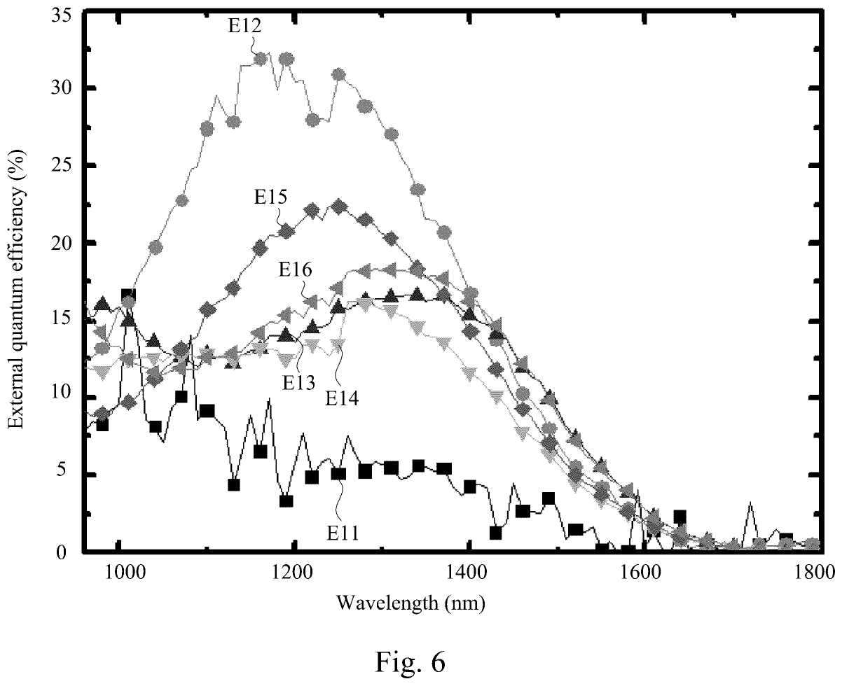

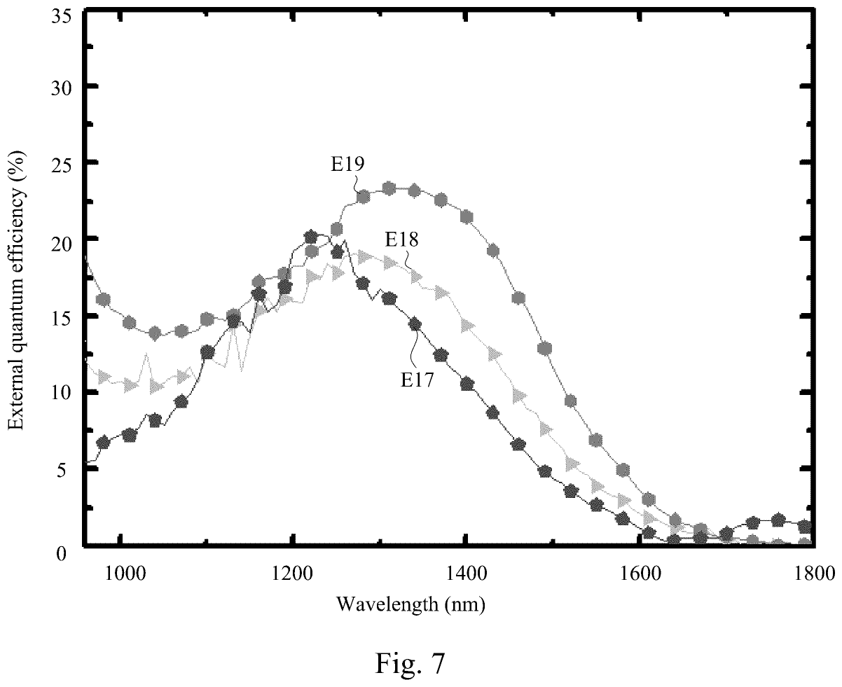

FIG. 2 is a schematic cross-sectional view of the photoelectric device modules 200 of Examples 1-23. As shown in FIG. 2, the photoelectric device module 200 includes a glass substrate 210, an Ag layer 220, a ZnO layer 230, a photoelectric conversion layer 240, a MoO₃ layer 250, and an IZO layer 260 that are stacked from bottom to top. The photoelectric device module 200 is top-illuminated, so the photoelectric device module 200 is measured by applying light L2 from above. Please refer to FIG. 4 to FIG. 8 for the measurement results. FIG. 4, FIG. 5, FIG. 6, FIG. 7, and FIG. 8 are external quantum efficiency-wavelength diagrams of the photoelectric device modules 200 of Examples 1-7, 8-10, 11-16, 17-19, and 20-23, respectively. The external quantum efficiencies were measured at −4V. It is worth noting that the photoelectric device module 200 has a micro-cavity that is the space between the upper surface of the Ag layer 220 and the lower surface of the IZO layer 260. Therefore, the light L2 can be reflected between the Ag layer 220 and the IZO layer 260. In more detail, after entering the photoelectric device module 200, the light L2 can be reflected by the Ag layer 220 to pass through the ZnO layer 230, the photoelectric conversion layer 240, and the MoO₃ layer 250 again, and then be reflected by the IZO layer 260, thereby increasing the absorption amount of the photoelectric conversion layer 240.

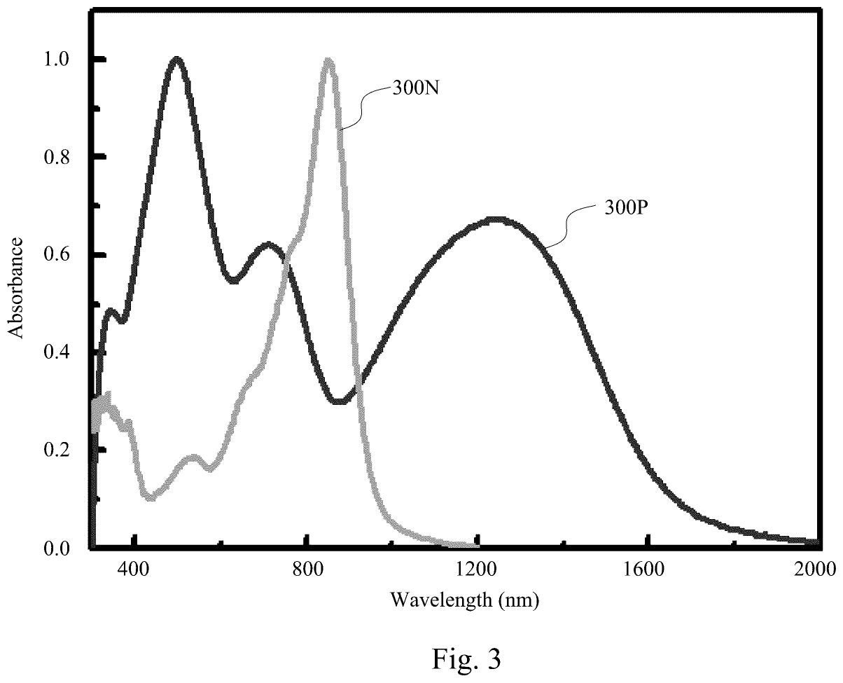

The photoelectric conversion layers 240 of Examples 1 to 19 include a P-type organic semiconductor and a N-type organic semiconductor that can respond to SWIR light. FIG. 3 shows an absorption spectrum 300P of the P-type organic semiconductor and an absorption spectrum 300N of the N-type organic semiconductor, in which the P-type organic semiconductor has the energy of the highest occupied molecular orbital (HOMO) of −4.91 eV and the energy of the lowest unoccupied molecular orbital (LUMO) of −4.16 eV. The N-type organic semiconductor has the energy of the HOMO of −5.73 eV and the energy of the LUMO of −4.42 eV. The manufacturing method of each photoelectric device module 200 of Examples 1-19 included the following operations. The P-type organic semiconductor and the N-type organic semiconductor with a molar ratio of 1:2 were dissolved in the solvent o-xylene to obtain a mixed solution with a solid content of 30 mg/mL. The mixed solution was spin-coated on the ZnO layer 230 and was annealed at 100° C. for 5 minutes to form the photoelectric conversion layer 240. The MoO₃ layer 250 and the IZO layer 260 were then deposited in sequence.

The photoelectric conversion layers 240 of Examples 20-23 include a P-type organic semiconductor and a N-type organic semiconductor that can respond to SWIR light, which are respectively

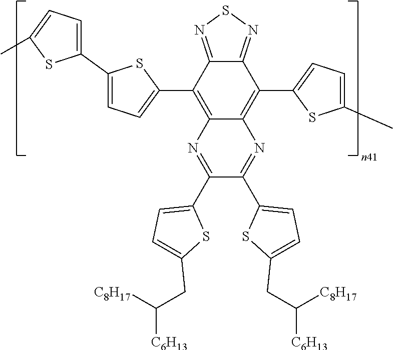

and

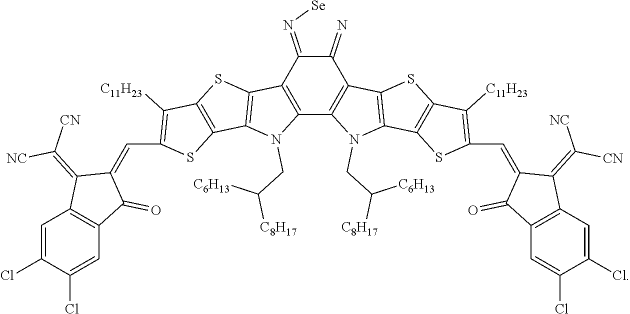

The manufacturing method of each photoelectric device module 200 of Examples 20-23 included the following operations. The P-type organic semiconductor and the N-type organic semiconductor with a molar ratio of 1:0.75 were dissolved in the solvent chloroform to obtain a mixed solution with a solid content of 21 mg/mL. The mixed solution was spin-coated on the ZnO layer 230 and was annealed at 100° C. for 5 minutes to form the photoelectric conversion layer 240. The MoO₃ layer 250 and the IZO layer 260 were then deposited in sequence.

Please refer to the following Table 1 for the structure parameters and FE measurement results of the photoelectric device modules 200 of Examples 1 to 23.

TABLE 1

| | | | | | | Maximum | |
|---|---|---|---|---|---|---|---|
| | | | Thickness of | | | response | |
| | Thickness | Thickness | photoelectric | Thickness | Thickness | wavelength | |
| | of Ag | of ZnO | conversion | of MoO₃ | of IZO | above 1000 nm | EQE at |
| Example | layer (nm) | layer (nm) | layer (nm) | layer (nm) | layer (nm) | and its EQE | 1300 nm |
| 1 | 75 | 30 | 138 | 10 | 150 | 1000 nm, 9.5% | 6.8% |
| 2 | 75 | 30 | 192 | 10 | 150 | 1050 nm, 19.8% | 11.5% |
| 3 | 75 | 30 | 243 | 10 | 150 | 1160 nm, 22.6% | 14.9% |
| 4 | 75 | 30 | 303 | 10 | 150 | 1190 nm, 20.3% | 17.5% |
| 5 | 75 | 30 | 321 | 10 | 150 | 1280 nm, 19.5% | 18.8% |
| 6 | 75 | 30 | 346 | 10 | 150 | 1310 nm, 15.9% | 15.5% |
| 7 | 75 | 30 | 408 | 10 | 150 | 1360 nm, 12.6% | 11.6% |
| 8 | 75 | 30 | 330 | 10 | 150 | 1160 nm, 23.2% | 20.1% |
| 9 | 75 | 60 | 330 | 10 | 150 | 1260 nm, 25.8% | 24.0% |
| 10 | 75 | 100 | 330 | 10 | 150 | 1270 nm, 24.9% | 23.9% |
| 11 | 75 | 30 | 250 | 10 | 90 | 1170 nm, 10% | 5.7% |
| 12 | 75 | 30 | 300 | 20 | 120 | 1170 nm, 32.3% | 27.6% |
| 13 | 75 | 30 | 350 | 40 | 150 | 1330 nm, 16.7% | 16.5% |
| 14 | 75 | 60 | 250 | 20 | 150 | 1270 nm, 16.2% | 15.8% |
| 15 | 75 | 60 | 300 | 40 | 90 | 1240 nm, 22.4% | 20.6% |
| 16 | 75 | 60 | 350 | 10 | 120 | 1290 nm, 18.4% | 18.3% |
| 17 | 75 | 100 | 250 | 40 | 120 | 1240 nm, 20.4% | 16.2% |
| 18 | 75 | 100 | 300 | 10 | 150 | 1270 nm, 19.1% | 18.7% |
| 19 | 75 | 100 | 350 | 20 | 90 | 1330 nm, 23.3% | 23.1% |
| 20 | 75 | 30 | 130 | 10 | 150 | 1000 nm, 6.9% | 1.7% |
| 21 | 75 | 30 | 180 | 10 | 150 | 1110 nm, 5.5% | 2.4% |
| 22 | 75 | 30 | 230 | 10 | 150 | 1180 nm, 1.9% | 1.8% |
| 23 | 75 | 30 | 330 | 10 | 150 | 1000 nm, 0.8% | 0.7% |

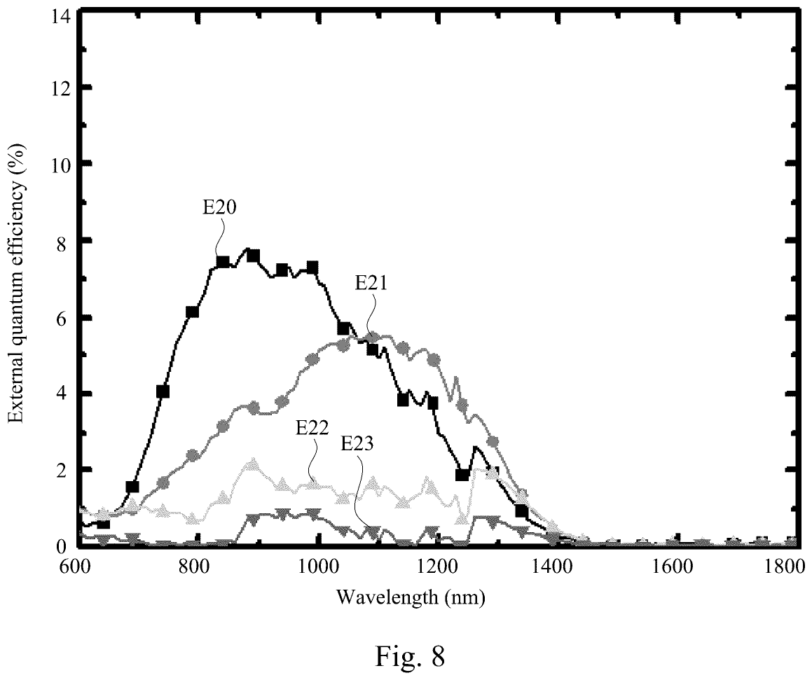

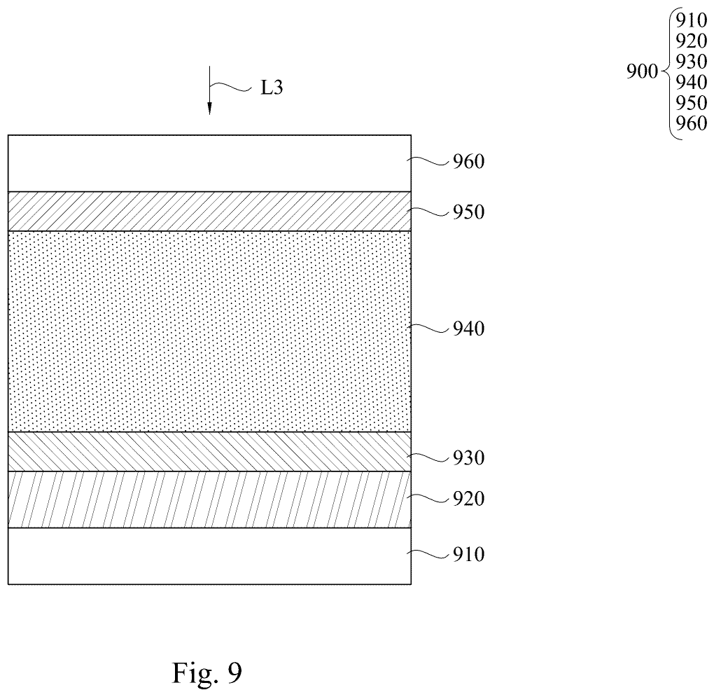

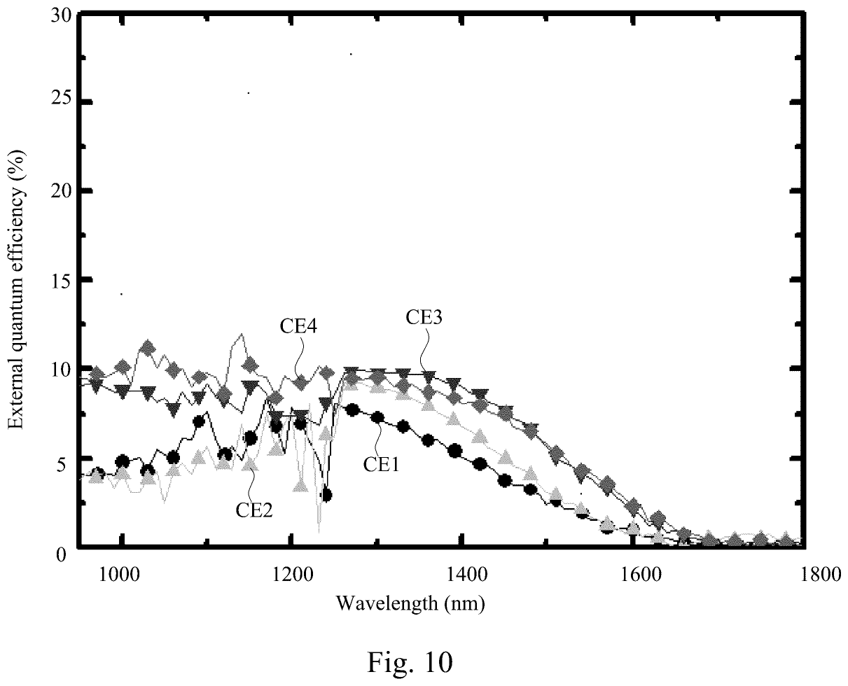

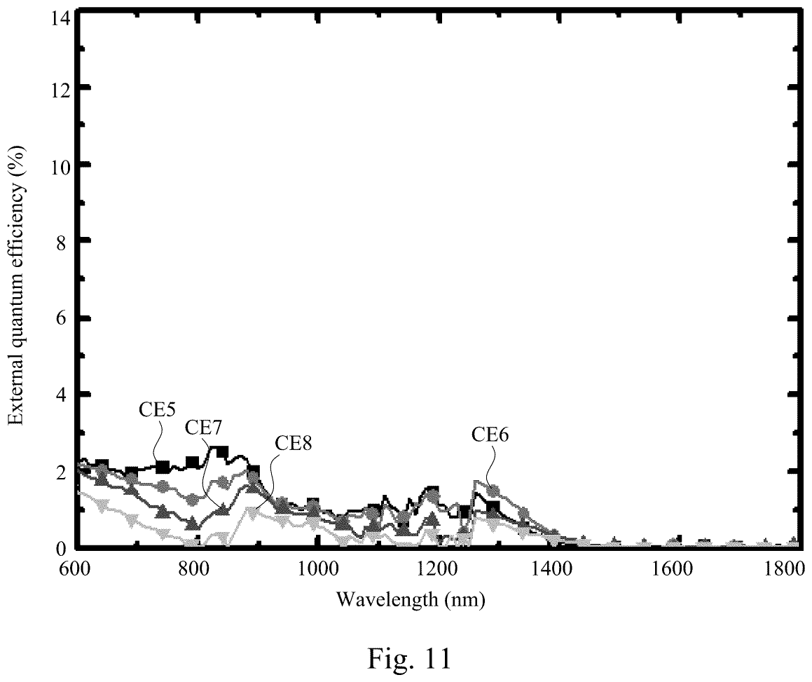

FIG. 9 is a schematic cross-sectional view of the photoelectric device modules 900 of Comparative Examples 1-8. As shown in FIG. 9, the photoelectric device module 900 includes a glass substrate 910, an ITO layer 920, a ZnO layer 930, a photoelectric conversion layer 940, a MoO₃ layer 950, and an IZO layer 960 that are stacked from bottom to top. The photoelectric device module 900 is top-illuminated and does not have a micro-cavity. The photoelectric conversion layers 940 of Comparative Examples 1-4 are the same as the photoelectric conversion layers 240 of Examples 1-19, so FIG. 3 is also the absorption spectrum 300P of the P-type organic semiconductor and the absorption spectrum 300N of the N-type organic semiconductor of the photoelectric conversion layers 940 of Comparative Examples 1-4. The photoelectric conversion layers 940 of Comparative Examples 5-8 are the same as the photoelectric conversion layers 240 of Examples 20-23. The photoelectric device module 900 is measured by applying light L3 from above. Please refer to FIG. 10 and FIG. 11 for the measurement results. FIG. 10 and FIG. 11 are external quantum efficiency-wavelength diagrams of the photoelectric device modules 900 of Comparative Examples 1-4 and Comparative Examples 5-8, respectively. Please refer to the following Table 2 for the structure parameters and EQE measurement results of the photoelectric device modules 900 of Comparative Examples 1-8.

TABLE 2

| | | | | | | Maximum | |
|---|---|---|---|---|---|---|---|
| | | | Thickness of | | | response | |
| | Thickness | Thickness | photoelectric | Thickness | Thickness | wavelength | |
| Comparative | of ITO | of ZnO | conversion | of MoO₃ | of IZO | above 1000 nm | EQE at |
| Example | layer (nm) | layer (nm) | layer (nm) | layer (nm) | layer (nm) | and its EQE | 1300 nm |
| 1 | 150 | 30 | 142 | 10 | 150 | 1250 nm, 8.0% | 7.3% |
| 2 | 150 | 30 | 208 | 10 | 150 | 1280 nm, 9.2% | 9.0% |
| 3 | 150 | 30 | 273 | 10 | 150 | 1280 nm, 9.9% | 9.8% |
| 4 | 150 | 30 | 328 | 10 | 150 | 1140 nm, 12.0% | 9.5% |
| 5 | 150 | 30 | 130 | 10 | 150 | 1180 nm, 1.6% | 1.0% |
| 6 | 150 | 30 | 180 | 10 | 150 | 1260 nm, 1.8% | 1.4% |
| 7 | 150 | 30 | 230 | 10 | 150 | 1260 nm, 1.0% | 0.8% |
| 8 | 150 | 30 | 330 | 10 | 150 | 1260 nm, 0.8% | 0.6% |

Please refer to Examples 1 to 7 of Table 1, FIG. 2, and FIG. 4. FIG. 4 is an external quantum efficiency-wavelength diagram of the photoelectric device modules 200 of Examples 1 to 7. The photoelectric device modules 200 of Examples 1 to 7 have a micro-cavity. It can be seen from the curve E1 of Example 1, the curve E2 of Example 2, the curve E3 of Example 3, the curve E4 of Example 4, the curve E5 of Example 5, the curve E6 of Example 6, and the curve E7 of Example 7 that as the thickness of the photoelectric conversion layer 240 increases, the EQE also increases due to the increase in light absorption, and the maximum wavelengths of different curves have a red shift phenomenon. When the thickness of the photoelectric conversion layer 240 is greater than 303 nm, the red shift phenomenon still occur, which means that the micro-cavity still affects the photoelectric device module 200, but the EQE decreases slightly, which indicates that the EQE may be affected by the carrier transfer capability of the photoelectric conversion layer 240. Please further refer to Comparative Examples 1 to 4 in Table 2, FIG. 9, and FIG. 10. FIG. 10 is an external quantum efficiency-wavelength diagram of the photoelectric device modules 900 of Comparative Examples 1-4. It can be seen from the curve CE1 of Comparative Example 1, the curve CE2 of Comparative Example 2, the curve CE3 of Comparative Example 3, and the curve CE4 of Comparative Example 4 that the photoelectric device modules 900 of Comparative Examples 1-4 do not have a micro-cavity, so they cannot exhibit effective EQEs in the SWIR band. Moreover, the EQE cannot be effectively improved even if the thickness of the photoelectric conversion layer 940 is adjusted.

Please refer to Examples 8-10 of Table 1, FIG. 2, and FIG. 5. It can be seen from the curve E8 of Embodiment 8, the curve E9 of Embodiment 9, and the curve E10 of Embodiment 10 that when the thickness of the ZnO layer 230 increases, the EQE of the photoelectric device module 200 can also increase accordingly. The ZnO layer 230 has an electron transport capability and can serve as an optical spacer to appropriately adjust the light field and effectively distribute photons into the photoelectric conversion layer 240, thereby improving the EQE of the photoelectric device module 200.

Please refer to Examples 11-19 of Table 1, FIG. 2, FIG. 6, and FIG. 7. While the thickness of the Ag layer 220 is fixed, the thicknesses of the ZnO layer 230, the photoelectric conversion layer 240, the MoO₃ layer 250, and the IZO layer 260 are adjusted to adjust the thickness of the micro-cavity, thereby optimizing the EQE of the photoelectric device module 200. FIG. 6 shows the curve E11 of Example 11, the curve E12 of Example 12, the curve E13 of Example 13, the curve E14 of Example 14, the curve E15 of Example 15, the curve E16 of Example 16, the curve E17 of Example 17, the curve E18 of Example 18, and the curve E19 of Example 19. As shown in Example 12, the photoelectric device module 200 can have the EQE as high as 27.6% under light irradiation with a wavelength of 1300 nm.

Please refer to Examples 20-23 of Table 1, FIG. 2, and FIG. 8. FIG. 8 is an external quantum efficiency-wavelength diagram of the photoelectric device modules 200 of Examples 20-23. The photoelectric device modules 200 of Examples 20-23 have a micro-cavity. It can be seen from the curve E20 of Example 20, the curve E21 of Example 21, the curve E22 of Example 22, and the curve E23 of Example 23 that as the thickness of the photoelectric conversion layer 240 increases, the maximum wavelengths of different curves have a red shift phenomenon. Moreover, the EQE can be further optimized by adjusting the thickness of the photoelectric conversion layer 240. Please further refer to Comparative Examples 5-8 of Table 2, FIG. 9, and FIG. 11. FIG. 11 is an external quantum efficiency-wavelength diagram of the photoelectric device modules 900 of Comparative Examples 5-8. It can be seen from the curve CE5 of Comparative Example 5, the curve CE6 of Comparative Example 6, the curve CE7 of Comparative Example 7, and the curve CE8 of Comparative Example 8 that the photoelectric device modules 900 of Comparative Examples 5-8 do not have a micro-cavity, so they cannot exhibit effective EQEs in the SWIR band. Moreover, the EQE cannot be effectively improved even if the thickness of the photoelectric conversion layer 940 is adjusted.

In summary, the present disclosure provides a photoelectric device module and an operation method thereof. The photoelectric device module includes a substrate, a first reflective layer, a photoelectric conversion layer, and a second reflective layer that are stacked in sequence from bottom to top, and can receive light from above. Since the first reflectivity of the first reflective layer is greater than the second reflectivity of the second reflective layer, light can be easily reflected by the first reflective layer and enters the photoelectric conversion layer again, thereby increasing the light absorption of the photoelectric conversion layer, and thereby increasing the external quantum efficiency (EQE) and photocurrent of the photoelectric device module.

Although the present disclosure has been described in considerable detail with reference to certain embodiments, other embodiments are possible. Therefore, the spirit and scope of the appended claims should not be limited to the description of the embodiments contained herein.

It will be apparent to those skilled in the art that various modifications and variations can be made to the structure of the present disclosure without departing from the scope or spirit of the present disclosure. In view of the foregoing, it is intended that the present disclosure cover the modifications and variations of the present disclosure falling within the scope of the appended claims.

What is claimed is:

1. A photoelectric device module, comprising:
a substrate;
a first reflective layer disposed on the substrate, wherein the first reflective layer has a first reflectivity;
a photoelectric conversion layer disposed on the first reflective layer and having a thickness of greater than or equal to 135 nm; and
a second reflective layer disposed on the photoelectric conversion layer, wherein the second reflective layer has a second reflectivity, and the first reflectivity is greater than the second reflectivity.

2. The photoelectric device module of claim 1, wherein the thickness of the photoelectric conversion layer is 135 nm to 500 nm.

3. The photoelectric device module of claim 1, wherein the first reflective layer has the first reflectivity of greater than or equal to 50%, and the second reflective layer has the second reflectivity of greater than or equal to 5%.

4. The photoelectric device module of claim 3, wherein the second reflectivity is less than or equal to 50%.

5. The photoelectric device module of claim 1, further comprising a carrier transport layer disposed between the first reflective layer and the photoelectric conversion layer or between the photoelectric conversion layer and the second reflective layer.

6. The photoelectric device module of claim 5, wherein the carrier transport layer has a thickness of 10 nm to 100 nm.

7. The photoelectric device module of claim 1, wherein the first reflective layer has a thickness of greater than or equal to 50 nm.

8. The photoelectric device module of claim 1, wherein the first reflective layer comprises silver, aluminum, copper, gold, titanium, tungsten, molybdenum, titanium nitride, or combinations thereof.

9. The photoelectric device module of claim 1, wherein the second reflective layer has a thickness of 50 nm to 300 nm.

10. The photoelectric device module of claim 1, wherein the second reflective layer includes a transparent conductive oxide, a transparent conductive polymer, silver nanowires, a metal-containing layer with a thickness of less than or equal to 15 nm, or combinations thereof.

11. The photoelectric device module of claim 1, wherein the photoelectric conversion layer has an optical energy gap of less than or equal to 1.24 eV.

12. The photoelectric device module of claim 11, wherein the thickness of the photoelectric conversion layer is 135 nm to 500 nm.

13. The photoelectric device module of claim 1, further comprising a carrier transport layer disposed between the first reflective layer and the photoelectric conversion layer, wherein the carrier transport layer is a hole transport layer or an electron transport layer.

14. The photoelectric device module of claim 13, wherein the carrier transport layer has a thickness of 10 nm to 100 nm.

15. The photoelectric device module of claim 1, wherein the first reflective layer has the first reflectivity of greater than or equal to 50% for light with a wavelength of 600 nm to 2600 nm.

16. A method of operating a photoelectric device module, the method comprising:
receiving light by the photoelectric device module of claim 1, wherein an upper surface of the second reflective layer is a light-receiving surface.
